(19) United States
(12) Patent Application Publication
(10) Pub. No.: US 2024/0379498 A1
(43) Pub. Date: Nov. 14, 2024

(54) SEMICONDUCTOR PACKAGE FOR LIQUID IMMERSION COOLING AND METHOD OF FORMING THE SAME

(71) Applicants: ND-HI TECHNOLOGIES LAB, INC., TAIPEI CITY (TW); ETRON TECHNOLOGY, INC., HSINCHU (TW)

(72) Inventors: HO-MING TONG, TAIPEI CITY (TW); CHAO-CHUN LU, HSINCHU (TW)

(21) Appl. No.: 18/592,521

(22) Filed: Mar. 1, 2024

Related U.S. Application Data
(60) Provisional application No. 63/461,621, filed on Apr. 25, 2023.
(60) Provisional application No. 63/462,271, filed on Apr. 27, 2023.
(60) Provisional application No. 63/465,565, filed on May 11, 2023.
(60) Provisional application No. 63/583,008, filed on Sep. 15, 2023.

(51) Int. Cl. H01L 23/473; H01L 21/48; H01L 23/31; H01L 23/498

(52) U.S. Cl. CPC H01L 23/473; H01L 21/4853; H01L 23/3135; H01L 23/49816

(57) ABSTRACT

A semiconductor package includes: a first semiconductor die disposed over a first substrate; a plurality of second semiconductor dies disposed over the first semiconductor die or adjacent to the first semiconductor die; a plurality of first connectors arranged between and electrically connecting the first semiconductor die and the first substrate; a plurality of second connectors arranged between and electrically connecting two of the second semiconductor dies; a first dielectric layer encapsulating the plurality of second connectors; and a dielectric coating, different from the first dielectric layer, conformally formed on exposed surfaces of the plurality of first connectors and laterally surrounding the first dielectric layer. A plurality of air gaps are arranged between the plurality of first connectors.

### PRIORITY CLAIM AND CROSS-REFERENCE

This application claims the benefit of U.S. provisional application No. 63/461,621 filed on Apr. 25, 2023, U.S. provisional application No. 63/583,008 filed on Sep. 15, 2023, U.S. provisional application No. 63/462,271 filed on Apr. 27, 2023, and U.S. provisional application No. 63/465,565 filed on May 11, 2023, the disclosures of which are incorporated by reference herein in its entirety.

### FIELD

This disclosure relates in general to a semiconductor device and a method of forming the same, and more particularly to a semiconductor device for liquid immersion cooling and a method of forming the same.

### BACKGROUND

Tremendous progress has been made in geometrical scaling of transistors in conventional two-dimensional (2D) integrated circuits (ICs) due to the continual improvements of engineering and material science involving techniques such as extremely complex multiple-step lithographic patterning, new strain enhancing materials and metal oxide gate. However, 2D device scaling is losing momentum as the aforementioned techniques approach their practical limits. Three-dimensional (3D) IC integration which represents a radical departure from the traditional 2D IC integration has been recognized as a next-generation semiconductor technology to simultaneously achieve high performance, low power consumption, small physical size and high integration density. The 3D ICs provide a path to continually meet performance and cost demands of next generation devices while still permitting more relaxed gate lengths with less process complexity for high-end applications such as high-performance computing (HPC), data centers and artificial intelligence (AI).

3D IC integration can proceed through monolithic integration or integration of disparate dies. 3D monolithic integration involves typically vertical integration of multiple active silicon layers with vertical interconnects between the layers. Recently, a “cache-on-central processing unit (CPU)” 3D IC structure has been demonstrated and commercialized using copper hybrid bonding. Today, high-bandwidth-memory (HBM) dynamic random-access memory (DRAM) stacks, each of which created by vertically integrating a number of DRAM dies on a control IC, represent the highest volume commercial 3D ICs. These HBM DRAM stacks are typically mounted side-by-side with a processor IC on a silicon interposer in 2.5D IC packaging (see FIG. 1) for high-end applications such as HPC, data centers and AI. A 2.5D IC typically contains through-silicon vias (TSVs) in active dies such as DRAMs and control ICs, and in the silicon interposer which can be passive or active. A 2.5D IC can also contain redistribution layers (RDLs) in the interposer and active dies. Take ChatGPT for instance, it is powered by nVidia's H100 GPU in 2.5D IC configuration. H100 is the world's most powerful GPU today and it dissipates an astounding 700 W/chip. Going forward, 3D ICs can enable memory on memory, memory over logic, and logic over logic structures using interconnect technologies including TSVs, RDLs containing interconnect wiring and micro-vias, flip-chip bonding based on copper pillar micro-bumps or solder bumps, as well as the newly emerged technique of copper hybrid bonding.

3D ICs created by heterogeneous integration or monolithic integration allow for vertical stacking of heterogeneous dies or active silicon layers made from different manufacturing processes and nodes, chip/chiplet reuse, and chiplets-in-SiP (system-in-a-package). Ultimately, 3D IC integration will enable stacking of HBM DRAM stacks on processors to greatly shorten the time of data transfer between DRAM dies and the processor and greatly reduce the peak compute-memory bandwidth gap. 3D ICs are ideal for applications that require integration of more transistors in a given footprint (such as mobile system-on-chip (SoC)) or for applications already pushing the capability limit of a single die at the most-advanced node, such as HPC, data centers, AI, machine learning, 5G/6G networks, computer graphics, smartphones/wearables, automotive and others that demand ultra-high-performance, higher-power-efficiency devices. These devices include CPU, GPU (graphics processing unit), FPGA (field-programmable gate array), ASIC (application-specific IC), TPU (tensor processing unit), integrated photonics, AP (application processor for cell phones), packet buffer/router devices, and the like.

To accelerate adoption, 3D IC systems must be designed in a holistic manner via IC-package-system co-design, which involves silicon IPs, ICs/chiplets, IC packages and system boards, and addresses accompanying power and thermal challenges. In contrast to PPAC (performance, power, area and cost) optimization per square centimeter as applied in 2D packaging, IC-package-system co-design for 3D ICs aims to achieve “PPAC optimization per cubic millimeter”, wherein a vertical dimension that covers the IC, the interposer, the IC package substrate, the IC package and the system printed circuit board (PCB) must all be considered in all tradeoff decisions.

Today, all 3D ICs comprising cache-on-CPU and 2.5D ICs comprising HBM DRAM stacks (a type of 3D IC) adopt heat dissipation topologies based on air cooling or direct-to-chip liquid cooling with a heat spreader attached through the use of a thermal interface material (TIM) to the backside of the processor (and HBM DRAM stacks in 2.5D IC) and either an air cooled heatsink or an liquid cooled cold plate attached to the backside of the heat spreader to dissipate the heat from chip hot spots. However, as the operating powers of processors in the 2.5D ICs continue to increase to beyond 700 W/chip, say to 1000 W/chip or higher, the aforementioned heat dissipation technologies are no longer adequate or best suited to maintain the operating temperatures of the chips to below their optimal operating temperatures. More importantly, high processor powers prevent HBM stacks from being mounted on the processor to greatly reduce the data transfer times between the processor and the DRAM dies. This is one key reason why today the most powerful GPU is stilled placed side-by-side with the HBM stacks in the 2.5D IC configuration and with the GPU cooled through its backside. Therefore, thermal management involving high-power processors imposes a severe constraint on the processor power a 2.5D IC or a 3D IC can entertain particularly in support of HPC, data center and AI applications.

### SUMMARY

One aspect of the present disclosure provides a semiconductor package, which includes a first semiconductor die disposed over a first substrate; a plurality of second semiconductor dies disposed over the first semiconductor die or adjacent to the first semiconductor die; a plurality of first connectors arranged between and electrically connecting the first semiconductor die and the first substrate; a plurality of second connectors arranged between and electrically connecting two of the second semiconductor dies; a first dielectric layer encapsulating the plurality of second connectors; and a dielectric coating, different from the first dielectric layer, conformally formed on exposed surfaces of the plurality of first connectors and laterally surrounding the first dielectric layer. A plurality of air gaps are arranged between the plurality of first connectors.

Another aspect of the present disclosure provides a semiconductor package, which includes: a first semiconductor die arranged over a substrate; a plurality of second semiconductor dies over the first semiconductor die or adjacent to the first semiconductor die; a plurality of first connectors arranged between and electrically connecting the first semiconductor die and the substrate; a plurality of second connectors arranged between and electrically connecting two of the second semiconductor dies; a first dielectric layer encapsulating the plurality of second connectors; a plurality of enhancing structures adjacent to the first semiconductor die, wherein the plurality of enhancing structures are arranged proximal to the plurality of first connectors and the substrate, surrounding, or over the first semiconductor die; and a dielectric coating, different from the first dielectric layer, conformally formed on exposed surfaces of the plurality of first connectors and the plurality of enhancing structures, and laterally surrounding the first dielectric layer.

Yet another aspect of the present disclosure provides a method for manufacturing a semiconductor package. The method includes: forming a plurality of first connectors over a first semiconductor die; bonding the first semiconductor die to a substrate through the plurality of first connectors; forming a die stack over the first semiconductor die or adjacent to the first semiconductor die, wherein the die stack comprises a plurality of second semiconductor dies, a plurality of second connectors between two of the second semiconductor dies, and a first dielectric layer encapsulating the plurality of second connectors; and depositing a dielectric coating, different from the first dielectric layer, on exposed surfaces of the substrate, the plurality of first connectors, the first semiconductor die, the plurality of second semiconductor dies, and the first dielectric layer. The deposition of the dielectric coating leaves a plurality of air gaps between the plurality of first connectors.

In the present disclosure, novel 2.5D IC and 3D IC structures are proposed which exploit the use of a water-based liquid or a dielectric liquid as the coolant for liquid immersion cooling of the high-performance 2.5D IC and 3D IC structures. The exposed surfaces of the 2.5D IC or 3D IC mounted on a substrate (e.g., a laminate or an embedded substrate) and the printed circuit board (PCB) are completely protected by the deposition of a conformal dielectric coating, which can prevent undesired electrical conduction and/or other detrimental effects caused by the introduction of the water based or dielectric coolant that can penetrate into the interior of the 2.5D ICs and 3D ICs disclosed herein. Heat generated by the chip hot spots in the 2.5D ICs or 3D ICs can be removed through flows of the coolant in close contact with the dies in these package structures, thereby achieving highly efficient heat dissipation and maintaining desired operation temperatures for all the dies in the 2.5D ICs or 3D ICs.

### BRIEF DESCRIPTION OF THE DRAWINGS

Aspects of the present disclosure are best understood from the following detailed description when read with the accompanying figures. It should be noted that, in accordance with the standard practice in the industry, various structures are not drawn to scale. In fact, the dimensions of the various structures may be arbitrarily increased or reduced for clarity of discussion.

FIG. 1 shows a 2.5D IC package, according to comparative embodiments of the present disclosure.

FIG. 2 shows a schematic diagram of performance growth trends of the processor speed and the memory bandwidth, in accordance with some comparative embodiments of the present disclosure.

FIGS. 3A, 3B and 3C show block diagrams of memory architectures, in accordance with some embodiments of the present disclosure.

FIG. 4A shows a block diagram of a liquid immersion cooling system, in accordance with some embodiments of the present disclosure.

FIG. 4B shows a block diagram of a liquid immersion cooling system, in accordance with some embodiments of the present disclosure.

FIG. 4C shows a top view of a printed circuit board, in accordance with some embodiments of the present disclosure.

FIG. 5 shows a block diagram of a liquid immersion cooling system, in accordance with some embodiments of the present disclosure.

FIG. 6 shows a cross-sectional view of a semiconductor package, in accordance with various embodiments of the present disclosure.

FIGS. 7A and 7B show cross-sectional views of a semiconductor package, in accordance with various embodiments of the present disclosure.

FIGS. 8A and 8B show cross-sectional views of a semiconductor package, in accordance with various embodiments of the present disclosure.

FIGS. 9A and 9B show cross-sectional views of a semiconductor package, in accordance with various embodiments of the present disclosure.

FIGS. 10A, 10B, 10C and 10D show cross-sectional views of different CTE (coefficient of thermal expansion) adjusters, in accordance with various embodiments of the present disclosure.

FIGS. 11A and 11B show a cross-sectional view and a top view, respectively, of a semiconductor structure with an enhancing structure, in accordance with various embodiments of the present disclosure.

FIGS. 12A and 12B show a cross-sectional view and a top view, respectively, of a semiconductor structure containing an enhancing structure, in accordance with various embodiments of the present disclosure.

FIGS. 13A and 13B show cross-sectional views of two semiconductor structures containing different enhancing structures, in accordance with various embodiments of the present disclosure.

FIG. 14 shows a cross-sectional view of a semiconductor structure containing an enhancing structure, in accordance with various embodiments of the present disclosure.

FIGS. 15A and 15B show cross-sectional views of intermediate stages of forming a semiconductor structure with an enhancing structure, in accordance with some embodiments of the present disclosure.

FIGS. 16A, 16B and 16C show cross-sectional views of intermediate stages of forming a semiconductor structure with an enhancing structure, in accordance with some embodiments of the present disclosure.

FIG. 16D shows a top view of an intermediate stage of forming a semiconductor structure with an enhancing structure, in accordance with some embodiments of the present disclosure.

FIG. 17 shows a cross-sectional view of a semiconductor structure with an enhancing structure, in accordance with some embodiments of the present disclosure.

FIGS. 18A and 18B show a cross-sectional view and a top view, respectively, of a semiconductor structure with an enhancing structure, in accordance with some embodiments of the present disclosure.

FIG. 19 shows a cross-sectional view of a semiconductor structure with an enhancing structure, in accordance with some embodiments of the present disclosure.

FIGS. 20A and 20B show plan views of a substrate with an enhancing structure to facilitate heat dissipation, in accordance with various embodiments of the present disclosure.

FIG. 21 shows a schematic flow chart of a method of manufacturing a semiconductor package, in accordance with some embodiments of the present disclosure.

FIG. 22A shows a cross-sectional view of a semiconductor package, in accordance with some embodiments of the present disclosure.

FIG. 22B shows a cross-sectional view of a processor die in the semiconductor package shown in FIG. 22A, in accordance with some embodiments of the present disclosure.

FIGS. 22C and 22D show cross-sectional views of a semiconductor package, in accordance with various embodiments of the present disclosure.

FIG. 22E shows a cross-sectional view of a semiconductor package, in accordance with various embodiments of the present disclosure.

FIG. 22F shows a cross-sectional view of a processor die in the semiconductor package shown in FIG. 22E, in accordance with some embodiments of the present disclosure.

FIG. 22G shows a cross-sectional view of a semiconductor package, in accordance with some embodiments of the present disclosure.

FIGS. 23A, 23B and 23C show cross-sectional views of a semiconductor package, in accordance with various embodiments of the present disclosure.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawings. Further, like reference numerals across different figures dictate similar features, and therefore a detailed explanation of the similar feature may be provided when such features are first introduced in the disclosure, and may not be subsequently repeated.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” “on” and the like, may be used herein for case of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, although the terms such as “first,” “second” and “third” describe various elements, components, regions, layers and/or sections, these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context.

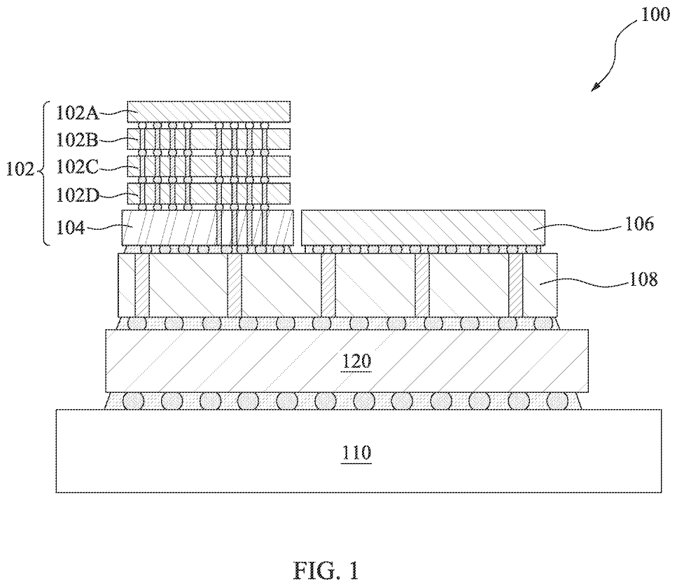

For high-end applications such as HPC, data centers and AI (artificial intelligence), the requirement of memory bandwidth and memory capacity is huge and ever-increasing in order to handle the skyrocketing data traffic. This has led to the proliferation of 3D HBM (high-bandwidth memory) DRAM stacks we are witnessing today. When it comes to 3D ICs, 3D HBM DRAM stacks are practically the largest volume, commercialized 3D IC today. A plurality of 3D HBM DRAM stacks are typically placed side-by-side and co-packaged with processors (or chiplets) on a 2.5D silicon interposer containing through silicon vias (TSVs) in the 2.5D IC configuration, as illustrated in FIG. 1. FIG. 1 shows a 2.5D IC package 100, according to comparative embodiments of the present disclosure. The IC package 100 includes a first substrate 110, a second substrate 120, a memory stack 102, a memory controller 104, a processor 106, and an interposer 108. The memory stack 102 includes a stack of DRAM ICs 102A, 102B, 102C and 102D, and the memory controller 104. According to some embodiments, an alternative to the interposer 108 is a laminate substrate containing embedded or substrate-mounted silicon interconnect bridges. The 3D HBM DRAM stacks such as the memory stack 102, typically contain 4 (for HBM1), 8 (for HBM2) and 12 (for HBM3) DRAM ICs vertically stacked on the memory controller 104. All DRAM ICs, 102A to 102D, in the HBM stacks 102 contain TSVs with the exception of the top DRAM IC 102A.

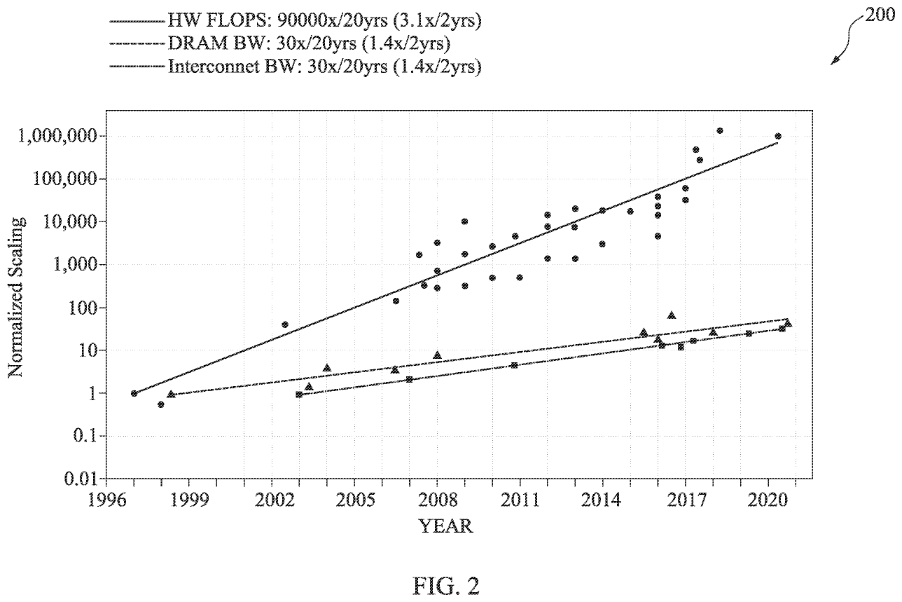

FIG. 2 shows a schematic diagram 200 of performance growth trends of the processor speed and the memory bandwidth, in accordance with some comparative embodiments of the present disclosure. As discussed previously, both HBM DRAM stacks and 2.5D ICs are maxing out on their capabilities to reap the full benefits of processor performance advancement going forward, particularly as the data traffic continues to soar. Going forward, the rate of advancement in the processor speed will continue to exceed the rate of advancement in the DRAM memory speed. The exponent of growth for processors is substantially larger than that of growth for DRAMs although each is improving exponentially. As shown in the schematic diagram 200, the interconnect bandwidth between the processor and the memory lags behind processor performance gains. This creates the “memory wall” effect which has prevented processor performance from being fully exploited. Memory latency and bandwidth will continue to limit system performance with sustained (streaming) memory bandwidth falling behind peak FLOP (floating-point operations), in which the peak FLOP rate can be seen in the exemplary dies, such as HBM1, HBM2 and nVidia's GPU A100. While the industry continues to demand even more computing performance, this imbalance has created a significant bottleneck that continues to grow larger each year even now despite the tremendous progress made in state-of-the-art IC and IC packaging advancements in the past decades

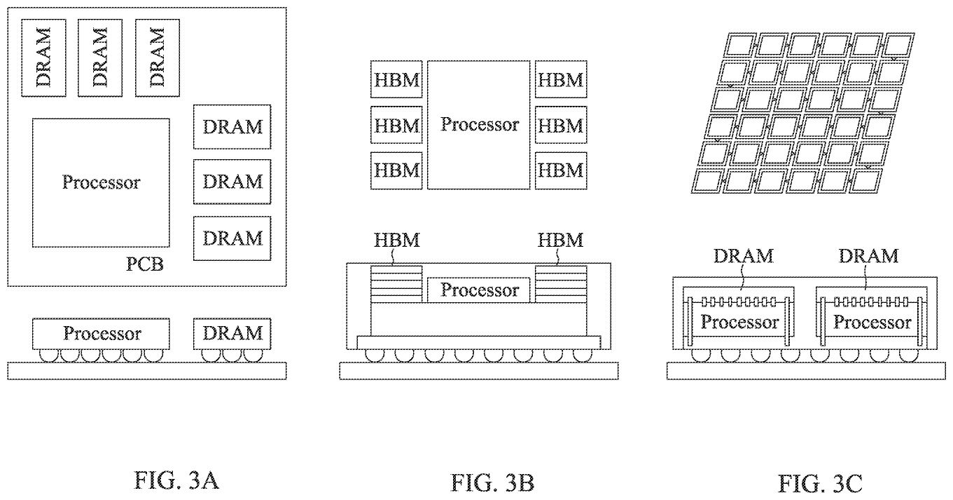

FIGS. 3A to 3C show block diagrams of memory architectures, in accordance with some embodiments of the present disclosure. Traditional compute systems involve processor and DRAM memory packages mounted on the printed circuit board (PCB), as illustrated in FIG. 3A. To mitigate the “memory wall” effect that comes with the traditional compute systems, near-memory computing and in-memory computing schemes have been proposed, as illustrated in FIGS. 3B and 3C, respectively. In FIGS. 3B and 3C, the near-memory computing scheme exemplified by 2.5D IC and the in-memory computing scheme exemplified by 3D IC involve moving memory from the PCB to near and have it placed side-by-side with the processor in the same package (in the case of 2.5D IC), or better yet right on top of the processor in the same package (in the case of 3D IC) to address the memory wall issue above.

Recent work has shown that certain memories can morph themselves into compute units by exploiting the physical properties of the memory cells, enabling in-situ computing in the memory array. Both the in- and near-memory computing schemes can circumvent overheads related to data movement with techniques that enable efficient mapping of data-intensive applications to such devices. Using the 2.5D and 3D IC architectures, the “memory wall” effect between processing engines and the main storage, e.g., the DRAM memory system, can be greatly alleviated through the low-latency, high-bandwidth connections to memory, afforded by the HBM stacks. The 3D IC architecture involving stacked HBM DRAM ICs on top of the processor in 3D IC is particularly attractive as it facilitates higher bandwidth between the HBM stacks and the processor, shorter data transfer time and lower power consumption compared to 2.5D ICs, while keeping other conditions identical. In line with the industry's drive towards near-/in-memory computing, the 3D HBM DRAM and processor in a 2.5D packaging architecture is migrating towards 3D IC, i.e., 3D memory-processor co-packaging in the vertical (package thickness) direction on a substrate. This development trend of 3D ICs will ultimately enable logic to logic, memory to memory and memory to logic stacking in 3D in order to achieve the ultimate integration densities.

Traditional IC packages mount the processor and memory at large distances on the printed circuit board (PCB). In contrast, a plurality of 3D HBM DRAM stacks for HPC, data centers and AI applications are typically placed much closer, e.g., within a few millimeters to the processor in 2.5D ICs. In microelectronic systems, data moves back and forth between processor and DRAM which is the main memory for most chips. High-end processors today need to dissipate much higher powers (e.g., up to 700 W/chip for GPUs and 400 W/chip for CPUs) compared to leading-edge HBMs (e.g., ˜15 W for HBM3) and processors in traditional compute systems. Moreover, driven by the continuing explosive growth of data traffic, processor powers are expected to continue to increase and are expected to exceed 2000 W/chip in the future, particularly for data centers. In contrast, 3D HBM DRAM systems offer lower power, higher bandwidth and higher density advantages compared to 2D memories mounted on the PCB. In a 3D HBM DRAM stack (for instance, in a HBM3 DRAM stack where 12 DRAM dies are stacked on a control die), the power per unit area can increase as a result of more-die stacking (with neighboring dies in the vertical stack heating each other) and the bottom-tier DRAM typically has limited heat dissipation paths compared to dies on the top-tier, which are closer to heat spreaders and heatsinks or cold plates. Both factors can contribute to overheating of 3D devices (compared to 2D memories) with the hotter tiers at the bottom and the cooler tiers at the top. High temperatures in a DRAM can result in reduced performance and efficiency, especially when dynamic thermal management schemes (software) are used to throttle DRAM bandwidth whenever the temperature gets too high. Overheating can also cause the devices to be stalled, i.e., prevented from being accessed, as well as reliability issues.

For high-end applications such as HPC, data centers and AI, placing a typically far-higher-power processor (e.g., CPU/GPU/FPGA) in close proximity to 3D memory such as HBM DRAM stacks further exacerbates these thermal issues even in 2.5D ICs. For thermal management of 2.5D ICs supporting the HBMs and processors, the industry has traditionally been resorting to the use of heat spreaders, thermal interface materials (TIMs) and heatsinks attached to the top side of the dies (mounted on the interposer) for air cooling and more so now for direct-to-chip liquid cooling with the use of cold plates replacing heatsinks. Data centers account for 1-1.5% of the world's total electricity consumption, and nearly half of that is spent solely on cooling everything in the data center. As the processor power continues to escalate, 2.5D ICs of the future and the migration from 2.5D ICs to 3D ICs will inevitably escalate thermal management challenges involving processors, memories and/or other logic devices in the 2.5D and 3D structures. This necessitates the development of new thermal management approaches covering liquid immersion cooling as well as new 2.5D IC and 3D IC heat spreading structures to maximize the utilities of these new thermal management approaches and ensure the dies in 3D ICs, particularly the bottom dies and middle-tier dies in vertical 3D stacks, operate at their optimum operating temperatures. As a result, both of 2.5D ICs and 3D ICs can allow for faster and far more efficient processor-memory operations and huge energy savings in comparison with air cooling and even direct-to-chip liquid cooling with the use of higher power processors while keeping pother conditions identical. With new thermal management techniques and new 2.5D and 3D structures, ever-higher-power/performance processors can therefore be integrated with ever-higher-performance HBM DRAM stacks (or other types of 3D memories) in close proximity (see FIGS. 3B and 3C) as the growth of data traffic continues to accelerate and as processor powers continue to increase particularly for high-end HPC, data center and AI applications. Even though HBM DRAM stacks are used in this invention for illustration, other suitable memories also apply.

Today, air cooling is still the norm for cooling data centers, and many enhanced cooling methodologies (e.g., calibrated vectored cooling, cold aisle/hot aisle containment, computer room air conditioner, etc.) are being implemented to enhance the efficiencies of air cooling. These improvements tend to be offset, however, by the ever-increasing processor power and amounts of computing entities and storage required to satisfy the insatiable demands of consumers for more data. Although air cooling technology has improved significantly in the recent past, it suffers from significant energy costs, a large data center space required, introduction of moisture into sealed environments, and frequent mechanical failures (e.g., related to fans). To cope with the escalating data traffic, researchers of data centers are starting to experiment on liquid cooling technologies such as liquid cooling with direct-to-chip liquid cooling in particular, which has been demonstrated to provide increased efficiency and effectiveness in cooling. Compared to air cooling systems which require a lot of power and bring with them pollutants and condensation into the data centers, liquid cooling systems can require less energy and lower operating cost, be cleaner, be more scalable, and be less dependent on the climate and location. As opposed to traditional air cooling, direct-to-chip liquid cooling can reduce power consumption by as much as 30% while reducing the rack space by 66%.

The present disclosure discloses innovative 2.5D IC and 3D IC stacking structures to maximize the benefits of liquid immersion cooling (for both single-phase and two-phase types). They involve the following:
(A) HBM DRAM and processor ICs (serving as an example; can be other types of dies), silicon interposer, substrate and PCB.
(B) The HBM dies are mounted one on top of the other, and on the interposer (in 2.5D IC) or the processor (in 3D IC) using copper pillar micro-bumps (serving as an example; can also be based on other types of interconnection techniques such as copper hybrid bonding) with or without the use of a non-conductive paste/film (NCP), wherein the 2.5D interposer is mounted on the substrate using larger C4 (controlled collapse chip connection) solder balls with or without the use of an underfill layer, and the substrate is mounted on the PCB using BGA solder balls with or without the use of an underfill layer.
(C) The use of a low-CTE (coefficient of thermal expansion), high-TC (thermal conductivity) substrate to minimize the thermal expansion mismatch stresses between the substrate and the interposer (in 2.5D IC), and between the substrate and the bottom IC such as the processor (in 3D IC), in which the solder joints on the peripheries of the interposer or the bottom IC are of particular importance.
(D) Edge reinforcement structures to strengthen the flip chip joints, particularly for the flip chip joints at die and/or interposer/substrate edges (that are characterized by greater distances to neutral points), particularly when no NCP is deployed.
(E) Joint reinforcement structures for improved joint reliability during operation, particularly when no NCP is deployed.
(F) Special bump structures consisting of tall micro-bumps, irregular micro-bumps and multiple-bump-in-one (covering both active and dummy bumps) which can be placed not only on the chip and/or interposer/substrate peripheries but also right on top of chip hot spots, in order to enhance cooling of hot spots and to enhance joint reliability, particularly when no NCP is deployed.
(G) Bump layout, optimized to facilitate heat or coolant flows between dies (or components) and to enhance overall heat dissipation, particularly when no NCP is deployed.
(H) The use of a combination of high-TC (thermal conductivity) components comprising heat spreader, heatsink, cold plate and TIMs on top of the 2.5D IC and 3D IC structures according to application requirements.
(I) The use of a liquid immersion system which can be a single-phase or a two-phase system based on a dielectric coolant (e.g., fluorocarbon or hydrocarbon) or a water-based coolant (e.g., water or water-ethylene glycol mixtures), in which the liquid immersion system can also involve forced circulation preferably directed at the hot chips (e.g., processors).
(J) The deposition of a thin conformal, pin-hole-free coating, notably, parylene, on the exposed surfaces of 2.5D IC and 3D IC structures and cooling structures covering ICs, interposer, substrate, PCB and electrical connectors, in order to protect the electronic components from the liquid coolant, particularly when water based coolants are used.
(K) The use of high-TC (and preferably low-CTE) interposers such as diamond interposers which use either bulk single crystal diamond (SCD) or polycrystalline diamond (PCD) as the substrate (with a thickness of typically 10 μm or higher) wherein the interposers contain redistribution layers (RDL) on both their top and bottom sides (for electrical and/or optical interconnection) which are connected by through vias, and wherein the through vias can be electrical vias, optical vias, thermal vias and/or fluidic vias.
(L) The use of ICs made of either silicon (or other type of semiconductor material) or a high-TC composite wafer such as a silicon-diamond bi-wafer or a silicon-diamond-silicon tri-wafer. In what follows, as you can see in the figures attached, any combination of the above features, (A) to (L), apply in this invention even though for brevity the figures as drawn may not contain certain features. Though not shown below, holes to facilitate close liquid coolant access to the hot dies can be created proximal to these dies in the interposer and/or in the package substrates. Furthermore, the methodologies, structures and processes disclosed herein apply to not only to 2.5D and 3D IC structures disclosed herein for demonstration but also to all other 2.x and 3D IC structures.

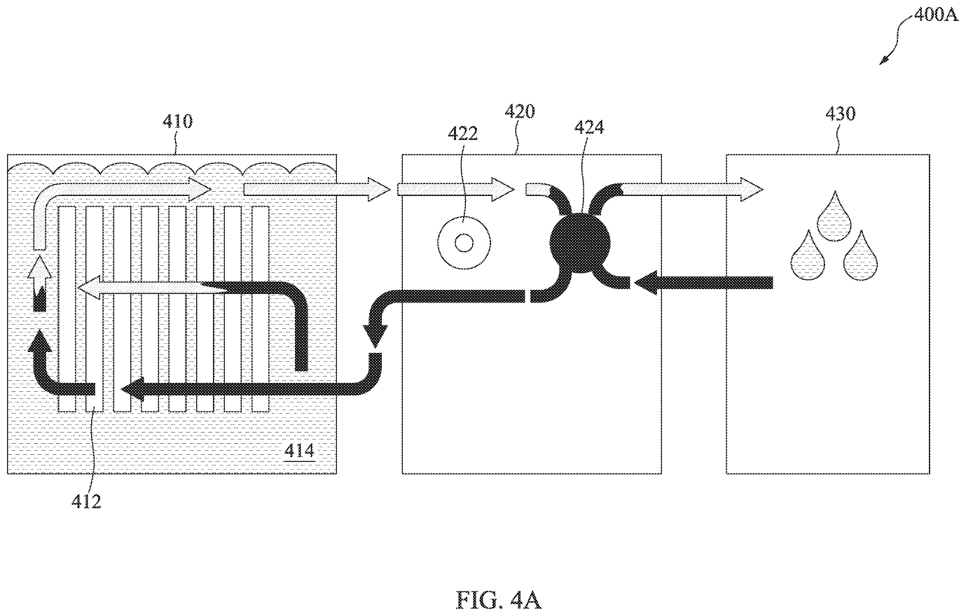

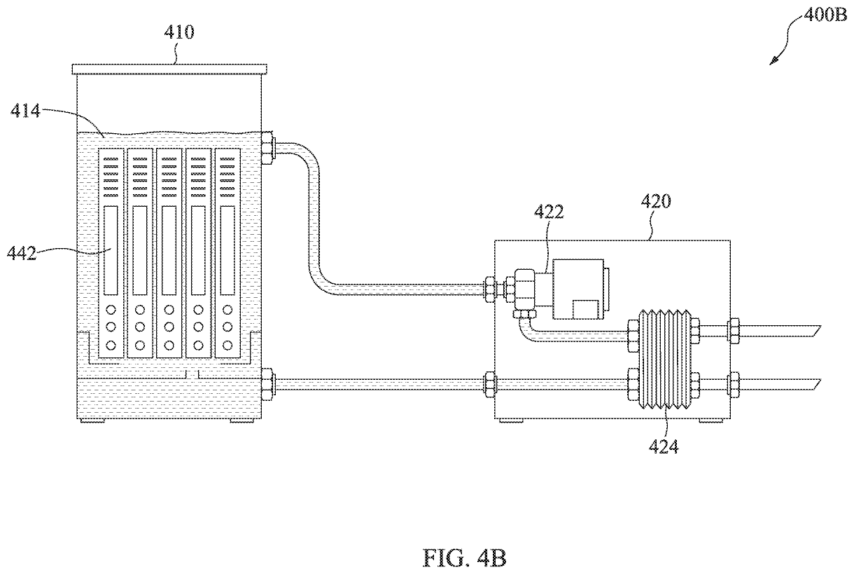

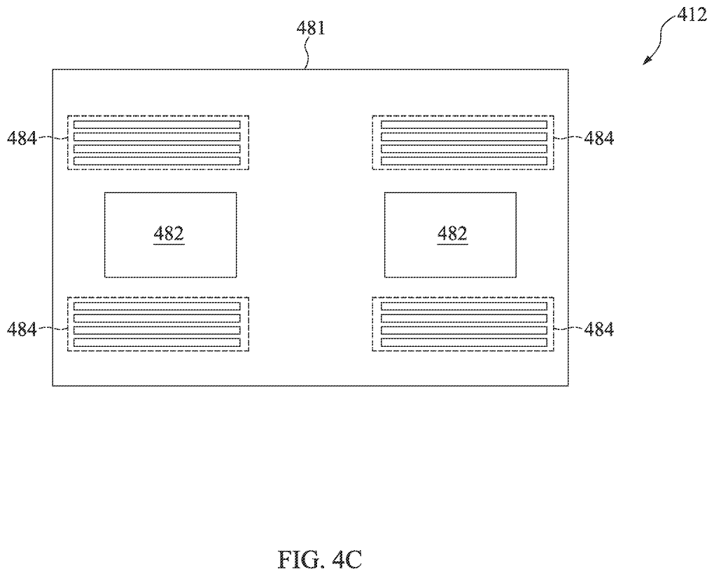

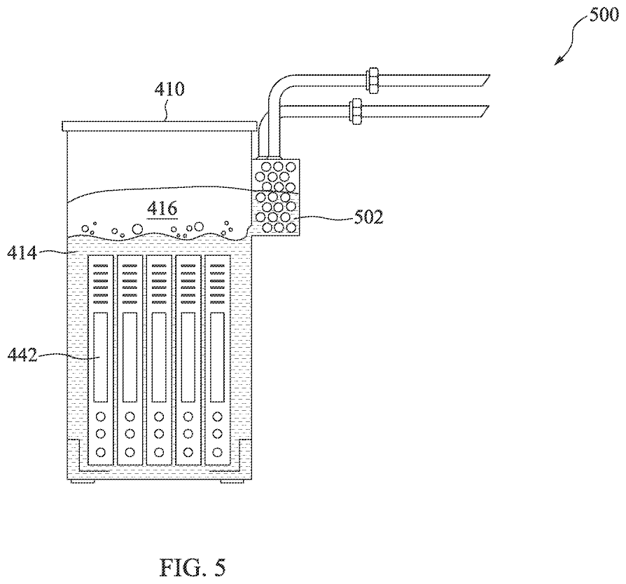

FIG. 4A shows a block diagram of a liquid immersion cooling system 400A, in accordance with some embodiments of the present disclosure. FIG. 4B shows a block diagram of a liquid immersion cooling system 400B, in accordance with some embodiments of the present disclosure. FIG. 4C shows the top view of an exemplary server board 412, in accordance with some embodiments of the present disclosure. FIG. 5 shows a block diagram of a liquid immersion cooling system 500, in accordance with some embodiments of the present disclosure.

There exist two common liquid cooling systems: liquid immersion cooling and direct-to-chip cooling. Referring to FIGS. 4A, 4A, 4C, liquid immersion cooling involves physically submerging computer components (e.g., a server board 412 shown in FIGS. 4A and 4C or 442 shown in FIG. 4B) in a tank 410 of a dielectric coolant 414 (or water based coolants), in which the dielectric coolant 414 can be a fluorocarbon or a hydrocarbon. Referring to FIG. 4C, the server board 412 as appeared in a traditional computing system (see FIG. 3A) includes a substrate 481 which is typically a PCB on which two exemplary processors 482 and four exemplary memory packages 484 are mounted. When 2.5D and 3D IC structures (see FIG. 1 for example) are involved, they will take the place of the processors and be mounted on the PCB. Liquid immersion cooling can be carried out via single-phase cooling or two-phase cooling. State-of-the-art immersion cooling systems today still rely on the use of non-electrically-conductive dielectric coolants for heat transfer. Single-phase and two-phase liquid immersion cooling systems do not require deployment of cooling fins and fans in the IT equipment, machine room refrigerated air conditioning system, raised access floor, etc. which are associated with air cooling and are therefore more energy efficient compared to their air cooled counterparts

Referring to FIG. 4A or 4B, in a single-phase liquid immersion cooling system, the liquid dielectric coolant 414 possesses a higher thermal conductivity compared to that of air. The dielectric coolant 414 is thermally but not electrically conductive, and is therefore relatively safe compared to electrically conductive water based solutions for the operation of computer components (such as server boards, 412 and 442) during liquid immersion cooling. Both the fluid coolant 414 and the hardware (such as server boards, 412 and 442) are contained within a leak-proof container, e.g., the tub 410. Liquid immersion cooling uses the liquid 414 to directly come in contact with the heat source (i.e., the hot chips) for better heat dissipation. The dielectric coolant 414 absorbs heat far more efficiently than air.

In the single-phase liquid immersion cooling system, the server boards 412 are typically immersed in a tank or tub 410 in a dielectric coolant 414. Heat generated by the server boards, 412 or 442, is conveyed through direct contact between the coolant 414 and the hot components on server boards, 412 or 442. Unlike the two-phase liquid immersion cooling, the single-phase cooling system (FIG. 4A) requires a pump 422 in the coolant distribution unit (CDU) 420 to suck the fluid into the CDU 420 that is equipped with a coolant-to-water heat exchanger 424 for cooling. The heated coolant 414 is, in turn, cooled using the heat exchanger 424 to complete the heat exchange cycle. Due to the high boiling point of the liquid coolant 414 used, the liquid coolant 414 will not vaporize so the liquid tank of a single-phase liquid immersion cooling system does not require a strict sealed design and environmental controls.

Referring to FIG. 5, in a two-phase liquid immersion cooling system, server boards 442 are immersed in the specially designed sealed tank 410. In some embodiments, the tank 410 uses typically a low-boiling-point dielectric coolant 414, so that the heat generated by server boards 442 can easily cause a phase change where the coolant 414 surrounding the components boils and generates vapor 416. The vapor 416, in turn, undergoes phase change through the condenser 502, returning the coolant 414 to the liquid state while removing heat. The sealed tank 410 maintains the phase change process through environmental controls, and the heat exchange process continues.

Direct-to-chip cooling (not shown in figures) utilizes pipes that deliver liquid coolant (e.g., water based liquid) directly into a cold plate that sits atop, for instance, a server board's chips to draw off heat. The extracted heat is subsequently fed to a chilled-water loop and transported back to the facility's cooling plant and released into the outside atmosphere. Direct-to-chip cooling may use either dielectric coolants or non-dielectric fluids (e.g., water based fluids). Although direct-to-chip liquid cooling provides far more efficient cooling solutions than air cooling for power-hungry data center equipment, liquid immersion cooling, which involves directly immersing chips in a liquid coolant, can be far more effective in carrying heat away from the hot spots of chips compared to direct-to-chip cooling, since the fluid never makes direct contact with the hot chips with the direct-to-chip cooling.

Although both single-phase cooling and two-phase cooling can be deployed with the present disclosure based on the use of an appropriate dielectric coolant, electrically conductive water and water-based fluids present advantages over dielectric coolants, and the conformal parylene coating disclosed herein allows them to be used as an option. According to a reported paper (Birbarah, et al., “Water Immersion Cooling of High Power Density Electronics,” International Journal of Heat Transfer, 147 (2020) 118918), the advantages associated with liquid immersion using water based solutions versus dielectric coolants include the following:
(A) On one hand, the single-phase cooling involving the use of a dielectric coolant is limited to relatively low heat transfer coefficients (<2 kW/m²K). On the other hand, the two-phase dielectric liquid cooling may suffer from hydrodynamic instabilities. Moreover, there exist three other disadvantages associated with the use of dielectric coolants:
(a) Low boiling point of non-polar coolant used for the two-phase cooling means that the electronic components cannot exceed the boiling temperature (e.g., 50° C.) by an appreciable amount due to the formation of a vapor blanket at its critical heat flux,
(b) The maximum heat flux attainable in the system equals the critical heat flux of the working fluid, which for nonpolar coolant is smaller (<20 W/cm²) than that required by future high power density systems (>100 W/cm²), and
(c) The dielectric fluid possesses relatively poor thermos-physical properties such as thermal conductivity, latent heat, and surface tension in comparison with water or water based fluids.
(B) The ultra-high latent heat of phase change (2.4 MJ/kg for water-glycol mixtures vs. 0.3 MJ/kg for dielectric fluids) and surface tension (50 to 73 mN/m for water-glycol mixtures vs. 5 mN/m for dielectric fluids) of water and water-glycol mixtures enable high boiling heat transfer, in which the heat transfer can come with an order of magnitude greater of the critical heat flux when compared to dielectric coolants, and
(C) Furthermore, operating temperatures of electronics at atmospheric pressures could be extended to 100° C. for water or higher for water glycol mixtures (107° C. for water-ethylene glycol mixture of 50-50% by volume) which can be nearer to the maximum chip operating temperatures for higher speeds.

Water-based fluids are currently utilized in many applications including automotive cooling. Therefore, the need for additional working fluids is eliminated for immersion cooling of electronics in these applications. To enable the use of water-based coolants, the 2.5D IC and 3D IC structures for liquid immersion cooling, however, must be sealed and protected with a pin-hole-free conformal coating such as parylene due to the electrical conductivity of water and water based liquids.

Besides using parylene as a thin conformal coating material for demonstration purposes in the present disclosure, particularly when water-based coolants are used, one can also use an alternative thin CVD conformal coating material particularly suitable for high-frequency RF applications. This material likely has to do with a precursor gas that consists of an initiator and at least one monomer comprising a cyclic siloxane and at least two vinyl groups. Such material can be formed by depositing a polymer from at least one monomer on the surface to be coated. Non-polymeric conformal coating materials such as ceramic insulators including TiO₂ and HfO₂ may also be considered as coating materials in place of parylene.

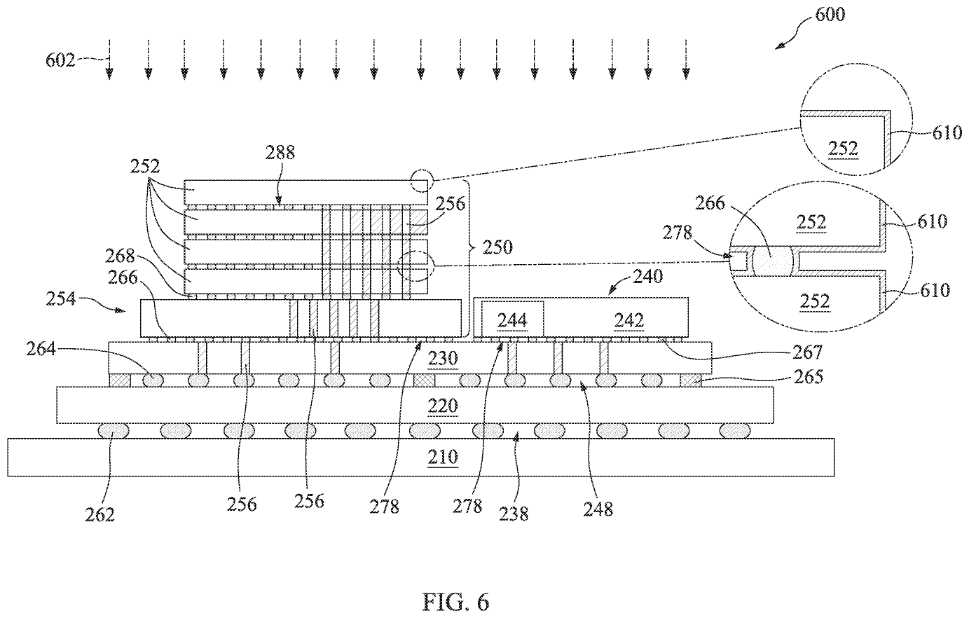

FIG. 6 shows a cross-sectional view of a semiconductor package 600, in accordance with some embodiments of the present disclosure. According to some embodiments, the semiconductor package 600 is a 2.5D IC. The semiconductor package 600 may include a first substrate 210, a second substrate 220, an interposer 230, a processor die 240, and one or more memory stacks 250 (only one exemplary memory stack 250 is shown for illustrative purposes).

According to some embodiments, the first substrate 210 is a printed circuit board (PCB) or a laminate substrate. The second substrate 220 can be a laminate substrate or an embedded substrate. According to some embodiments, the second substrate 220 can also be a semiconductor substrate made of materials including silicon, silicon carbide, silicon germanium, silicon-on-insulator, or other types of semiconductor materials. According to some embodiments, the second substrate 220 has a low CTE (coefficient of thermal expansion), which is lower than that of the first substrate 210. According to some embodiments, the second substrate 220 has a high TC (thermal conductivity) greater than that of the first substrate 210. According to some embodiments, the second substrate 220 may be formed of silicon, diamond, graphene, boron nitride, boron arsenide, cubic boron arsenide, aluminum nitride, silicon carbide, or a combination thereof to facilitate heat dissipation.

According to some embodiments, the interposer 230 is formed of a semiconductor material such as silicon, or other suitable materials, e.g., silicon carbide, silicon germanium, etc. According to some embodiments, the interposer 230 has a low CTE (coefficient of thermal expansion), which is lower than that of the first substrate 210 or the second substrate 220. According to some embodiments, the interposer 230 has a high TC (thermal conductivity) greater than that of the first substrate 210 or the second substrate 220. According to some embodiments, the interposer 230 may be formed of diamond, graphene, boron nitride, boron arsenide, cubic boron arsenide, aluminum nitride, silicon carbide, or a combination thereof to facilitate heat dissipation.

The interposer 230 may include RDLs on its top and bottom sides (not shown in FIG. 6) and one or more through vias 256 extending through the thickness of the interposer 230 in the vertical direction. The through vias 256 may therefore be referred to as through silicon via (TSV), through diamond via (TDV), through silicon-diamond via (TSDV), or the like depending on what type of substrate is used. The through vias 256 may serve the function of transmitting electrical signals, optical signals, dissipating heat (in the form of metallic thermal or fluidic vias), or a combination thereof. The RDLs and through vias 256 may be configured to electrically couple the processor die 240 to the memory stack 250. Additionally and alternatively, the through vias 256 are configured to conduct heat generated by the processor die 240 and/or the memory stack 250. According to some embodiments, the through vias 256 can be solid vias formed of conductive materials (covering conductive and barrier/adhesion layers) such as copper (Cu), titanium (Ti), titanium nitride (TiN), titanium-tungsten (TiW), tantalum (Ta), tantalum nitride (TaN), nickel-vanadium (NiV), chromium (Cr), phased chromium-copper, tungsten (W), aluminum (Al), silver (Ag), gold (Au), molybdenum (Mo), rhodium (Rh), cobalt (Co), ruthenium (Ru), iridium (Ir), platinum (Pt), palladium (Pd), osmium (Os) and combinations thereof, which are capable of transmitting electrical signals or power. According to some embodiments, the through vias 256 are formed of materials including a polymer, silicon, silicon dioxide, or the like, capable of transmitting optical signals. The basic structure of the vias 256 is a dielectric waveguide that consists of a longitudinally extended high-index optical medium, called the core, which is transversely surrounded by low-index media, called the cladding. A guided optical wave propagates in the waveguide along its longitudinal direction. Further, the through vias 256 may be fluidic vias (i.e., empty holes) capable of allowing coolant fluids to flow through for heat dissipation.

According to some embodiments, the processor die 240 includes a substrate 242 and a processor circuit 244. The substrate 242 may be formed of a material similar to that of the second substrate 220 or the interposer 230, e.g., silicon or a composite substrate comprising a semiconductor layer and a high-TC layer. The processor circuit 244 may include a CPU, a graphics processing unit (GPU), a field programmable gate array (FPGA), an ASIC (application-specific IC), a TPU (tensor processing unit), an integrated photonics, an AP (application processor for cell phones), a packet buffer/router device, and the like. The processor die 240 may be configured to perform predefined operations based on data provided by the memory stack 250 and store the processed data back to the memory stack 250.

According to some embodiments, the memory stack 250 is a die stack that includes a stack of memory dies 252 and a control die 254, wherein the memory dies 252 are stacked in the vertical direction on the control die 254. Each of the memory dies 252 may be a HBM DRAM die configured to store data to be accessed by the processor die 240 through the control die 254. According to some embodiments, the control die 254 is electrically coupled to the processor die 240 through the interposer 230 and the memory dies 252. The control die 254 may be configured to control the read and write operations of the memory dies 252 in the memory stack 250 and ensure smooth access of the memory cells in the memory dies 252 by the processor die 240.

According to some embodiments, each of the memory dies 252 (except for the topmost memory die 252) includes a plurality of through vias 256 extending through the thickness of the respective memory die 252. The through vias 256 may include a material similar to that of the through vias 256 of the interposer 230. Similarly, the control die 254 may include a plurality of through vias 256 extending through the thickness of the control die 254 in the vertical direction. The dies here can include RDLs as needed.

According to some embodiments, the semiconductor package 600 in FIG. 6 includes a plurality of connectors 262 between the first substrate 210 and the second substrate 220. The plurality of connectors 262 may be formed to bond and electrically couple the first substrate 210 to the second substrate 220. The connectors 262 may be implemented by solder bumps, e.g., a ball grid array (BGA), a land grid array (LGA), pin grid array (PGA), or other suitable conductive bumps. Similarly, according to some embodiments, the semiconductor package 600 includes a plurality of connectors 264 between the second substrate 220 and the interposer 230. The plurality of connectors 264 may be formed to bond and electrically couple the second substrate 220 to the interposer 230. According to some embodiments, the semiconductor package 600 further includes a plurality of connectors 266 between the interposer 230 and the processor die 240 and between the interposer 230 and the control die 254 in the memory stack 250. The plurality of connectors 266 may be formed to bond and electrically couple the interposer 230 to the processor die 240 and to the control die 254. Similarly, according to some embodiments, the semiconductor package 600 further includes a plurality of connectors 268 between the control die 254 and the bottom DRAM die 252, and between the plurality of memory dies 252. The plurality of connectors 268 may be formed to bond and electrically couple adjacent memory dies 252. The connectors 264, 266 and 268 may be implemented by solder bumps, e.g., solder joints, C4 (controlled collapse of chip connection) bumps, micro-bumps, copper hybrid bonds, or the like as warranted.

According to some embodiments, the aforementioned connectors, 262, 264, 266 and 268, are configured to dissipate heat to their underlying or overlying structures in addition to serving the functions of signal delivery and power transmission. The connectors, 262, 264, 266 and 268, may be formed of a solder or a metal.

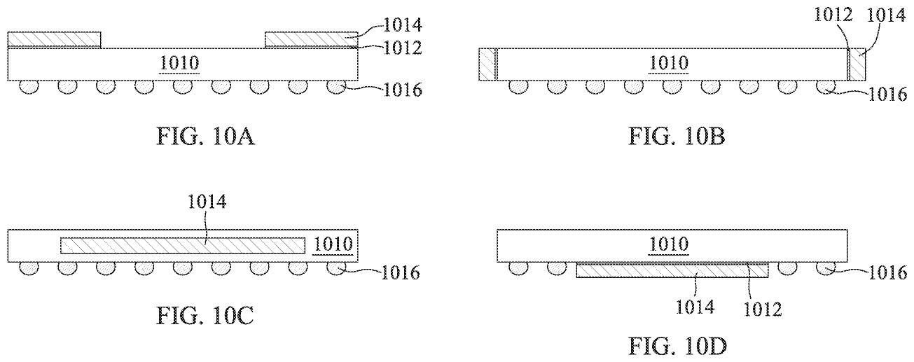

According to some embodiments, the semiconductor package 600 leaves the interstitial spaces between the connectors 262, 264, 266 and 268 empty without filling them with an encapsulation material or a dielectric layer such as a molding compound, a non-conductive paste (NCP) or an underfill. In this case, the semiconductor package 600 further includes a plurality of enhancing structures 265 between the second substrate 220 and the interposer 230, or a plurality of enhancing structures 267 between the interposer 230 and the processor die 240 and/or the control die 254. The enhancing structures, 265 and 267, may be used, respectively, to bond the second substrate 220 to the interposer 230, and to bond the interposer 230 to the processor die 240 and/or the control die 254. The enhancing structures, 265 and 267, can be used to reinforce the structural integrity of the semiconductor package 600, rendering the joints proximal to the enhancing structures less prone to failures caused by thermal expansion mismatch stresses between adjacent components The structures and configurations of the enhancing structures, 265 and 267 can be seen in FIG. 10A to FIG. 20.

According to some embodiments, water or a water-based liquid is used as the coolant to dissipate heat generated by the semiconductor package 600. In order to achieve the greatest heat dissipation efficiency, the water-based coolant is allowed to flow through the semiconductor package 600 and approach the hot spots as closely as possible with a liquid emersion cooling method. To this end, the electrical insulation between the water-based coolant and the semiconductor package 600 should be ensured. To achieve both of the aforementioned requirements, an electrically-insulated coating 610 is introduced to coat all the exposed surfaces of the semiconductor package 600.

According to some embodiments, the coating 610 is a dielectric coating formed of a dielectric material, such as parylene. The coating can be deposited uniformly over each exposed portion of the semiconductor package 600 to ensure the entire semiconductor package 600 is well protected from the water-based liquid during the liquid immersion cooling operation, including the lower feature surfaces under the connectors, 262, 264, 266 and 268, the upper feature surfaces over these connectors, and feature side surfaces exposed through these connectors. Referring to FIG. 6, enlarged views of two selected portions of the semiconductor package 600 are shown on the right side of FIG. 6, in which the coating 610 is conformally deposited along the corner of the memory die 252. Further, the gaps, 238, 248 and 278, are formed between the adjacent connectors, 262, 264 and 266, respectively, below or over the interposer 230. Similarly, the coating 610 is conformally deposited on the surfaces of the connectors 268 such that the gaps 288 between adjacent memory dies 252 between adjacent connectors 266 and between adjacent connectors 268 are left empty after the deposition of the coating 610. The gaps, 238, 248, 278 and 288, are defined by the coating 610. The gaps, 238, 248, 278 and 288, are useful to allow the water-based coolant (or equivalently, a dielectric coolant) to flow through in close proximity to the chip hot spots of the semiconductor package 600, e.g., the processor die 240 and/or the memory stack 250. Heat can be removed more efficiently by the water-based coolant, and the performance of the semiconductor package 600 can be enhanced.

The parylene (610 in FIG. 6) can be deposited through a chemical vapor deposition (CVD) operation 602, or other suitable deposition processes such as atomic layer deposition to achieve an ultrathin (down to 100 nm) pin-hole-free conformal coating. Parylene is the common name of a family of polymers which can be obtained by polymerization of para-xylylene. Parylene is applied in three stages using chemical vapor deposition (CVD). It deposits the material molecule by molecule onto parts placed in a vacuum chamber. This creates an extremely conformal pin-hole-free coating (e.g., down to 92 nm thickness with a thickness variation as small as 0.14 nm) that evenly covers grooves, crevices, gaps, and even sharp points in 3D with excellent thickness uniformity control. Prior to depositing parylene using CVD, a silane adhesion promoter can be applied to pre-cleaned parts. Parylene CVD is not a line-of-sight process and is able to achieve pin-hole free coatings even in tiny gaps hidden from sight between chips and substrates. Parylene can penetrate into tiny, deep crevices or openings as small as 0.1 μm or smaller in size on exposed part surfaces. Parylene has excellent electrical insulation properties and is often applied as an excellent conformal coating. Parylene possesses an ultra-high dielectric strength of 220-276 kV/mm, much greater than 20 kV/mm for epoxies (and that for AlN) and is stable up to 420° C. The thermal conductivity of Parylene can be 0.084-0.126 W/m·K depending on thicknesses. Certain variants of parylene (e.g., parylene AF-4) are thermally stable for up to 10 years at a long-term temperature limit of 350° C. Parylene can also be an extremely effective barrier against moisture and chemical. It can be etched using dry etching such as plasma etching, reactive ion etching or deep reactive ion etching (e.g., using SF₆ optimized O₂ plasma etching). Parylene finds utilities in liquid immersion cooling involving primarily water based coolants and can be applied to dielectric coolants for additional insurance as parylene can penetrate into and fill imperceptible tiny crevices and prevent them from forming crack nuclei for subsequent crack propagation and field failures during the operation of and the resultant thermal excursions imposed on the 2.5D and 3D ICs.

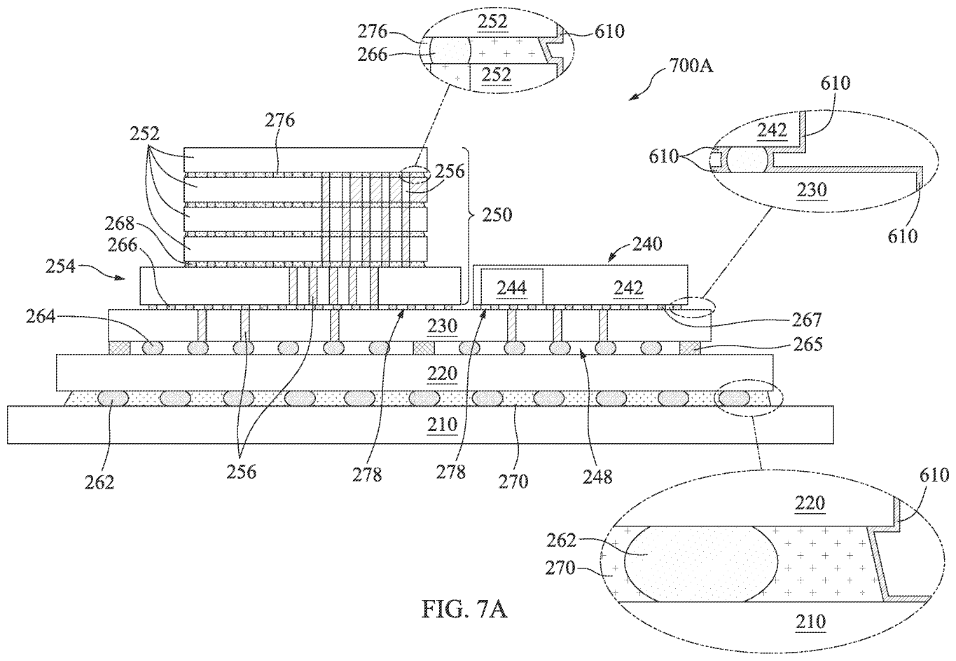

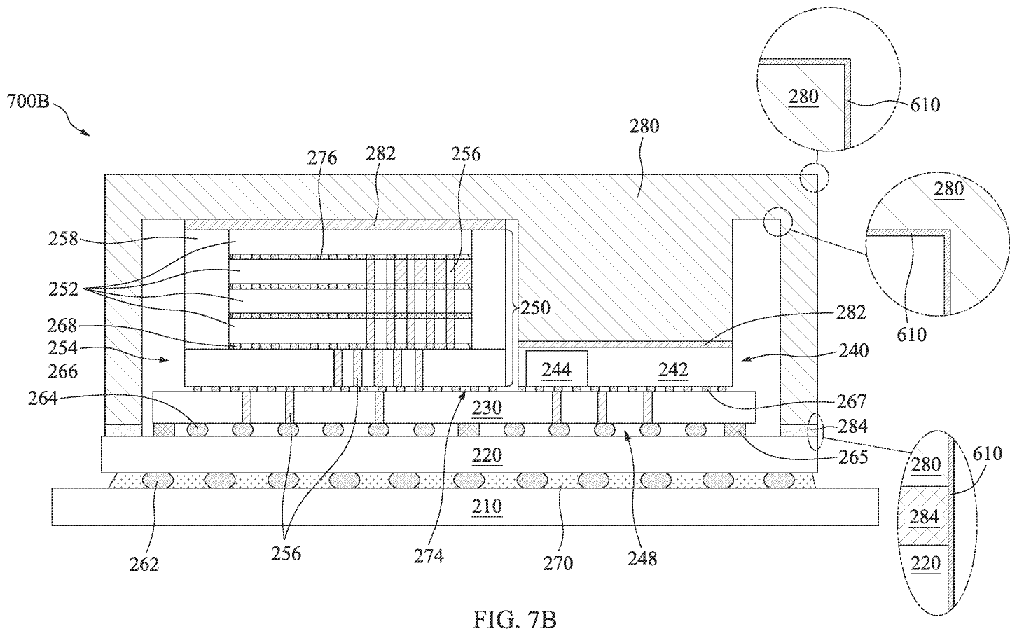

FIG. 7A shows a cross-sectional view of a semiconductor package 700A, in accordance with some embodiments of the present disclosure. The semiconductor package 700A is similar to the semiconductor package 600, and similar features are not repeated for brevity. Referring to FIGS. 6 and 7A, the main difference between the semiconductor package 700A and 600 is the introduction of dielectric layers, 270 and 276, to the semiconductor package 700A. According to some embodiments, the dielectric layer 270 or 276 is formed of a dielectric material, e.g., a NCP, an underfill or a molding compound. The presence of the dielectric layers, 270 and 276, fills the gaps, 238 and 288 that would otherwise exist as shown in FIG. 6. The presence of the dielectric layers, 270 and 276, can reinforce the structural integrity of the semiconductor package 700A between the first substrate 210 and the second substrate 220, and between the adjacent memory dies 252 and between the bottom memory die 252 and the control die 254. Further, the conformal coating 610 may be formed to laterally surround the dielectric layers, 270 and 276, in a conformal manner, as shown in an enlarged views of selected portions of the semiconductor package 700A on the right side of FIG. 7A.

According to some embodiments, connectors, 264 and 266, close to the hot spots located around the interposer 230, the processor circuit and hot spots 244 of the processor die 240 and the control die 254 are not encapsulated or surrounded by any encapsulation material or dielectric layer except for the coating 610. As a result, water-based coolants can freely flow through the gaps, 248 and 278, to provide enhanced heat dissipation performance. The enhancing structures, 265 and 267, can provide the needed mechanical support adjacent to the connectors, 264 and 266. The heat dissipation performance of the connectors, 262 or 268, may be somewhat degraded due to the presence of the encapsulation materials or dielectric layers, 270 and 276, there although such heat dissipation degradation is insignificant since memory dies do not dissipate much heat

FIG. 7B shows a cross-sectional view of a semiconductor package 700B, in accordance with some embodiments of the present disclosure. The semiconductor package 700B is similar to the semiconductor package 700A, and similar features are not repeated for brevity. Referring to FIGS. 7A and 7B, the main difference between the semiconductor package 700A and 700B is the introduction of a heat spreader 280 to the semiconductor package 700B. The heat spreader 280 may be arranged over the processor die 240 and the memory stack 250. In FIG. 7B, the thicknesses of the processor die 242 and the memory stack 250 can be the same as is often the case such that a flat heat spreader can be attached to the leveled backsides of the processor and memory stacks with a TIM. The heat spreader 280 may be used to dissipate heat generated by the semiconductor package 700B by heat conduction. The heat spreader 280 can be formed of a thermally conductive material, such as copper, aluminum, graphite, diamond, and a combination thereof. The heat spreader 280 can also be implemented with the inclusion of a vapor chamber. According to other embodiments, the material of the heat spreader 280 may include other materials, for example, graphene, boron nitride, boron arsenide, cubic boron arsenide, aluminum nitride, silicon carbide, or a combination thereof in 2.5D and 3D configurations.

According to some embodiments, the heat spreader 280 may have specific shapes, e.g., a plurality of fins in a heat sink design, to increase the heat dissipation area. According to some embodiments, the heat spreader 280 has a lid shape covering all the dies of the semiconductor package 700B. The heat spreader 280 may particularly cover the dies on two sides of the semiconductor package 700B as depicted in FIG. 7B or all four sides of the package while making provisions for empty spaces in the heat spreader to allow the coolant to have an easier and close access to the semiconductor package 700B to take the heat away. According to some embodiments, the heat spreader 280 exposes the semiconductor package 700B in the direction perpendicular to FIG. 7B.

In some embodiments, the semiconductor package 700B further includes a thermal interface material (TIM) 282 between the heat spreader 280 and the processor die 240, and between the heat spreader 280 and the memory stack 250. The TIM 282 may include various types, such as a thermal paste, a thermal adhesive, a thermal gap filler, a thermal tape, a phase-change materials, metal TIMs such as a solder, and the like. The TIM 282 may thermally couple the heat spreader 280 to the processor die 240 and the memory stack 250 to aid in the dissipation of heat generated by the processor die 240 and the memory stack 250. Similarly, the semiconductor package 700B further includes an adhesive layer 284 between the heat spreader 280 and the second substrate 220. The adhesive layer 284 may be used to couple the second substrate 220 to the heat spreader 280. The adhesive layer 284 may also be a high-TC paste or a TIM to thermally couple the heat spreader 280 to the second substrate 220 to aid in the dissipation of heat through the second substrate 220 which can contain thermal vias and thermal ground planes to help dissipate the heat.

According to some embodiments, the memory stack 250 further includes an encapsulation material 258 laterally surrounding the memory dies 252, the connectors 268 and the dielectric layers 276. The encapsulation material 258 can be arranged between the control die 254 and the TIM 282. The encapsulation material 258 can include a dielectric material, a molding compound, a thick-film photosensitive material and a polymeric material based on epoxy, polyimide (PI), benzocyclobutene (BCB), polybenzoxazole (PBO), polyetheretherketone (PEEK) or the like.

According to some embodiments, the conformal coating 610 is deposited to cover the exposed surfaces of the semiconductor package 700B. For example, as illustrated on the right side of FIG. 7B, the coating 610 covers the upper surface and side surfaces of the outer surface of the heat spreader 280, and the inner surfaces of the heat spreader 280. Although not separately shown, the coating 610 can also cover the exposed surfaces of the TIM 282, the adhesive layer 284, the outer surfaces of the encapsulation or dielectric material 258 and all other exposed surfaces in the semiconductor package 700 from die to PCB.

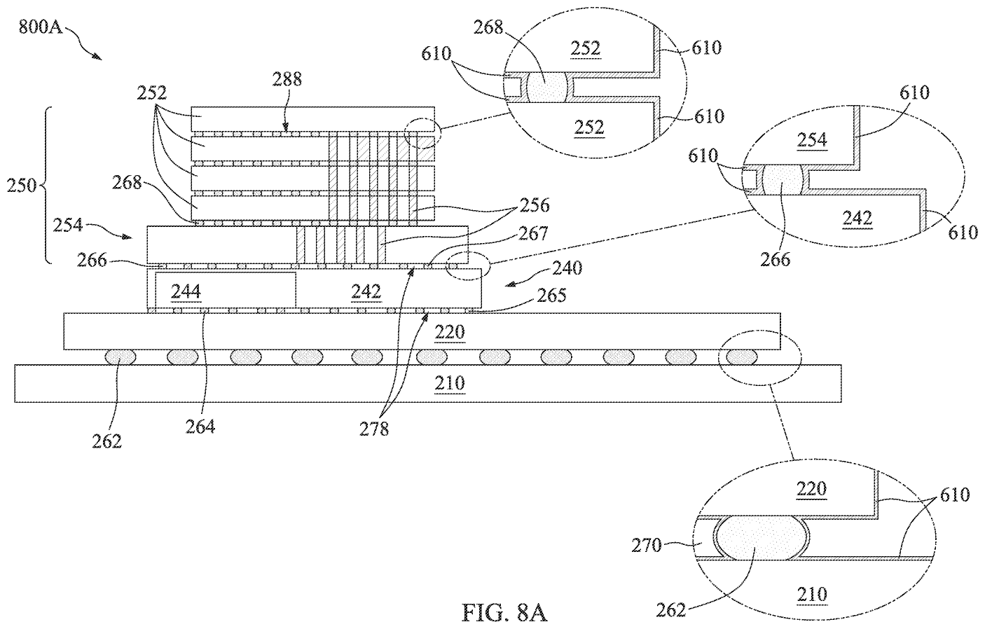

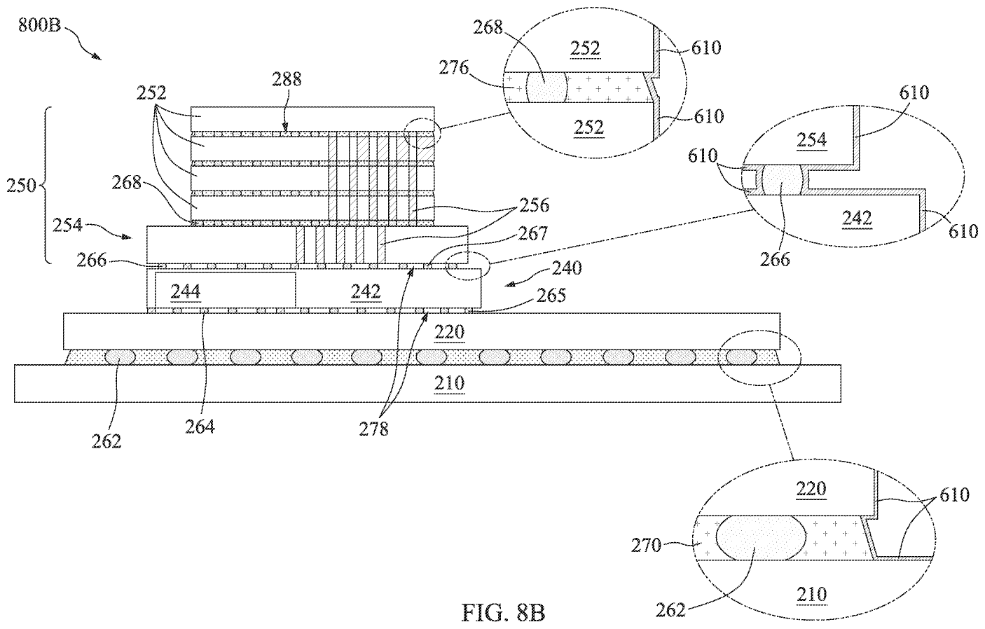

FIG. 8A shows a cross-sectional view of a semiconductor package 800A, in accordance with some embodiments of the present disclosure. According to some embodiments, the semiconductor package 800A is a 3D IC. The semiconductor package 800A may include a first substrate 210, a second substrate 220, a processor die 240, and one or more memory stacks 250 (only one exemplary memory stack 250 is shown herein for illustrative purposes). The semiconductor package 800A is similar to the semiconductor package 600 in many features, and similar features are not repeated for brevity. The main difference between the semiconductor package 800A and the semiconductor package 600 lies in different packaging techniques used, i.e., the semiconductor package 800A adopts the 3D IC structure in contrast to the 2.5D IC structure adopted in the semiconductor package 600. In other words, in the semiconductor package 800A, the first substrate 210, the second substrate 220, the processor die 240 and the memory stack 250 are stacked over one another in the vertical direction. Furthermore, the interposer die 230 that is present in the semiconductor package 600 can become the second substrate in the semiconductor package 800A. As can be seen in FIG. 8A, the length of the signal or power path between the processor die 240 and the memory stack 250 is further reduced in the semiconductor package 800A compared to the 2.5D package configuration of the semiconductor package 600 (even through the second substrate 220 in FIG. 8A is drawn to be much larger than needed so as to accommodate other dies). Power consumption, signal transmission speeds and data transfer rates can be further enhanced through the 3D IC configuration of the semiconductor package 800A over its 2.5D counterpart.

According to some embodiments, the conformal coating 610 is deposited to cover all the exposed surfaces the semiconductor package 800A. For example, as illustrated on the right side of FIG. 8A, the coating 610 covers the lower surface and the exposed surfaces of the memory die 252 and the connector 268, and the exposed surfaces of the control die 254, the processor die 240 and the connector 266. The coating 610 also covers the exposed surfaces of the first substrate 210, the second substrate 220 and the connector 262.

FIG. 8B shows a cross-sectional view of a semiconductor package 800B, in accordance with some embodiments of the present disclosure. The semiconductor package 800B is similar to the semiconductor package 800A, and similar features are not repeated for brevity. The main difference between the semiconductor package 800A and the semiconductor package 800B lies in the introduction of the encapsulation materials or dielectric layers, 270 and 276, to laterally surround the connectors, 262 and 268, respectively, as shown in FIG. 8B.

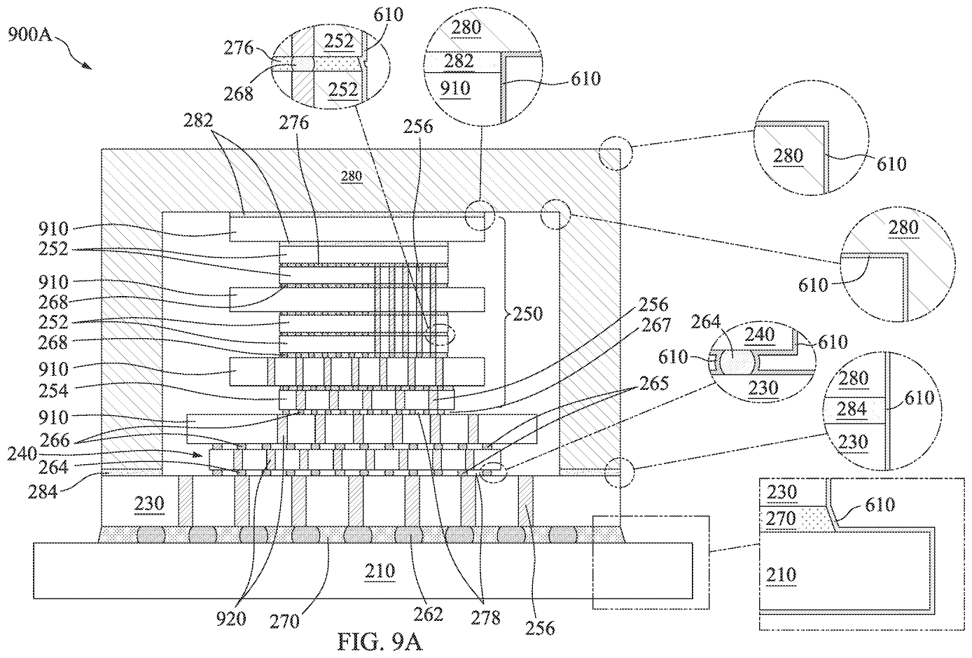

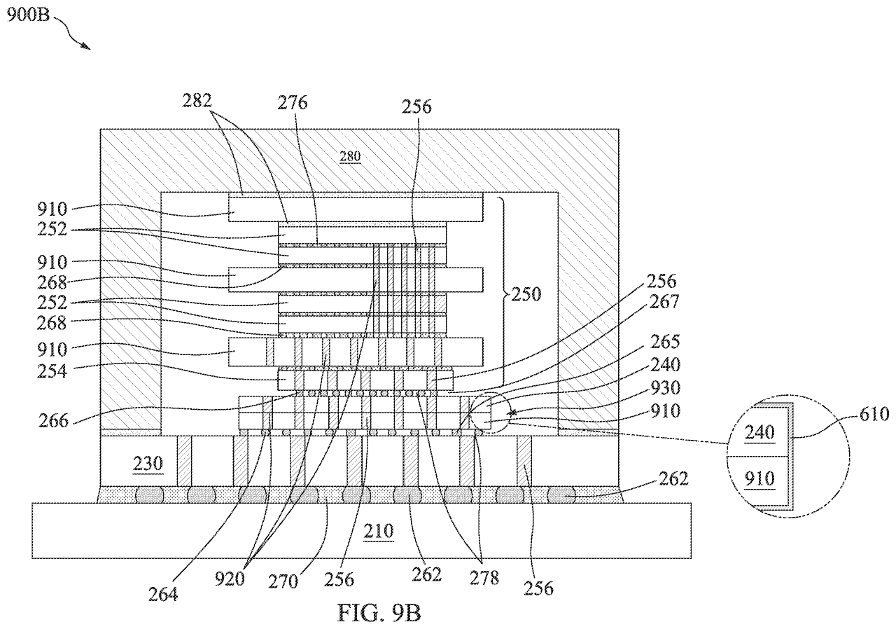

FIG. 9A shows a cross-sectional view of a semiconductor package 900A, in accordance with some embodiments of the present disclosure. The semiconductor package 900A is similar to the semiconductor package 800B, and similar features are not repeated for brevity. The main differences between the semiconductor package 900A and the semiconductor package 800B are: (a) the second substrate 220 is replaced with a high-TC interposer 230; and (b) the introduction of the heat spreader 280, the TIM 282 and the adhesive layer 284. The details of the interposer 230, the heat spreader 280, the TIM 282 and the adhesive layer 284 are similar to those described with reference to FIG. 7B, and therefore are not repeated for brevity.

According to some embodiments, the semiconductor package 900A further includes one or more high-TC heat spreaders 910 arranged between two adjacent components of the semiconductor package 900A to enhance the heat dissipation efficiency. For example, one heat spreader 910 may be arranged between the heat spreader 280 and the topmost memory die 252, another heat spreader 910 may be arranged between two intermediate memory dies 252, and yet another heat spreader 910 may be arranged between the bottommost memory die 252 and the control die 254. Additionally, still another heat spreader 910 may be arranged between the control die 254 and the processor die 240. According to some embodiments, the heat spreaders 910 is formed of diamond, graphene, boron nitride, boron arsenide, cubic boron arsenide, aluminum nitride, silicon carbide, copper-based material, a metal, a combination thereof, or the like. The material used to form the interposer 230 may also be similar to that used to form the heat spreader 910. According to some embodiments, the heat spreader 910 includes RDLs on its top and bottom sides and one or more through vias 920 extending through the thickness of the heat spreader 910. According to some embodiments, the through vias 920 can be solid vias formed of conductive materials such as copper (Cu), titanium (Ti), titanium nitride (TiN), titanium-tungsten (TiW), tantalum (Ta), tantalum nitride (TaN), nickel-vanadium (NiV), chromium (Cr), phased chromium-copper, tungsten (W), aluminum (Al), silver (Ag), gold (Au), molybdenum (Mo), rhodium (Rh), cobalt (Co), ruthenium (Ru), iridium (Ir), platinum (Pt), palladium (Pd), Osmium (Os) and combinations thereof, capable of transmitting electrical signals, power and heat. According to some embodiments, the through vias 920 are formed of materials including a polymer, silicon, silicon dioxide, or the like, capable of transmitting optical signals. The basic structure of a dielectric waveguide consists of a longitudinally extended high-index optical medium, called the core, which is transversely surrounded by low-index media, called the cladding. A guided optical wave propagates in the waveguide along its longitudinal direction. Further, the through vias 920 may be fluidic vias capable of allowing coolant fluids to flow through so as to dissipate heat.

The conformal coating 610 in FIG. 9A is coated on all the exposed surfaces of the semiconductor package 900A, in a manner similar to the coating 610 formed on the surfaces of the semiconductor packages, 600, 700A, 700B, 800A and 800B, as is illustrated in an enlarged views of some selected portions of the semiconductor package 900A on the right side of FIG. 9A.

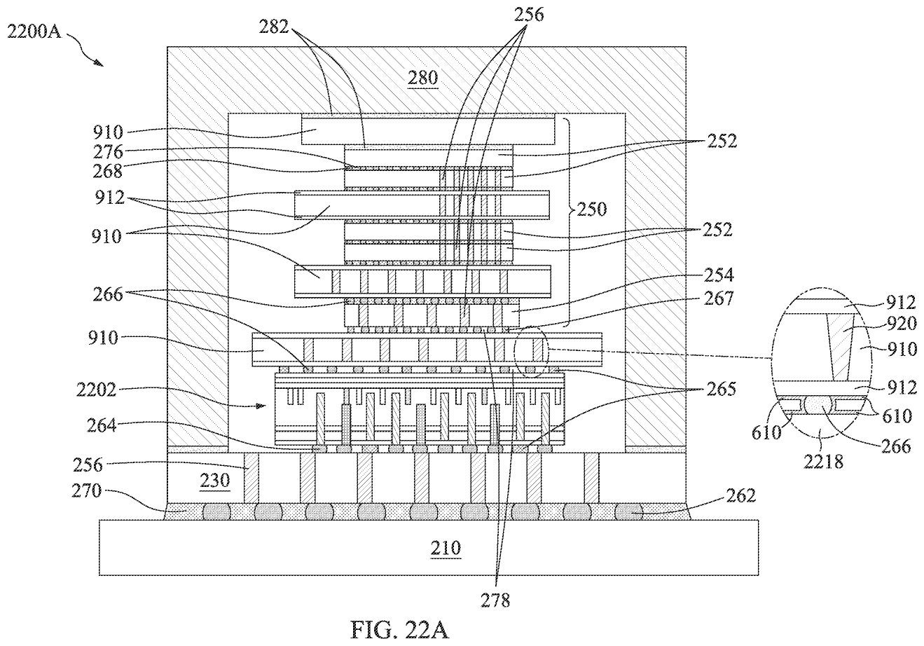

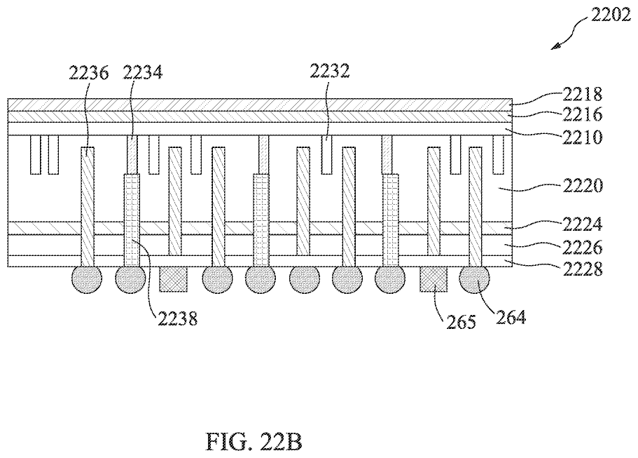

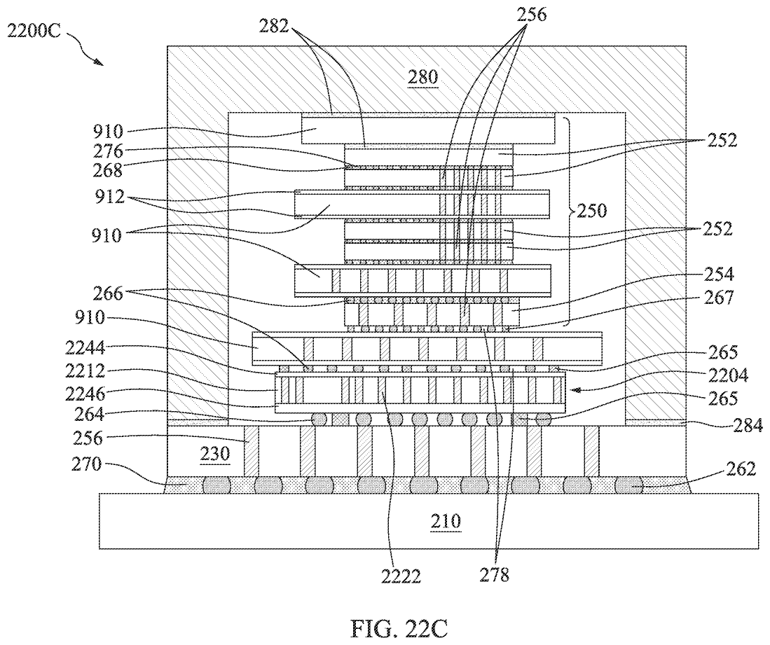

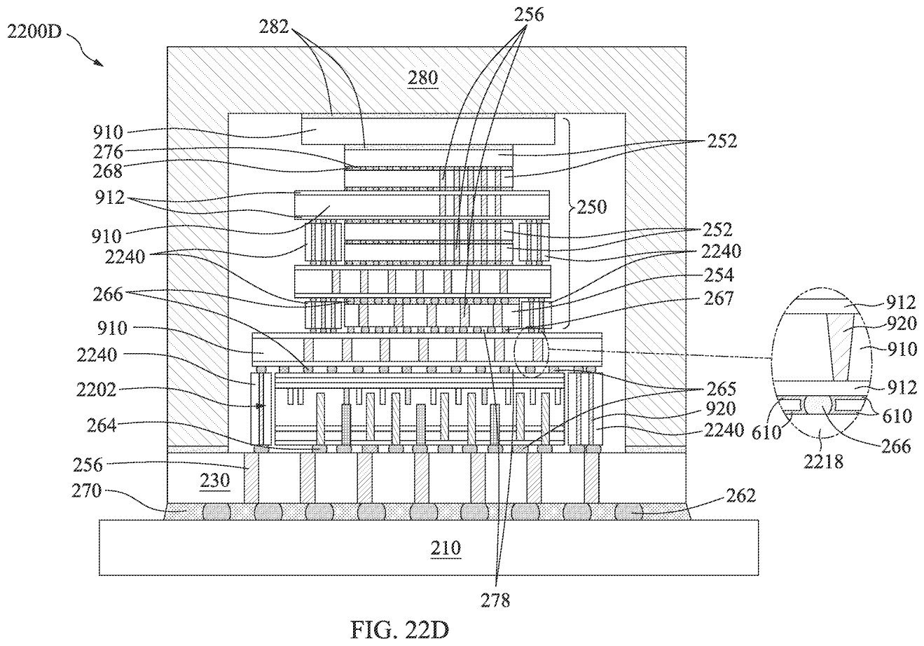

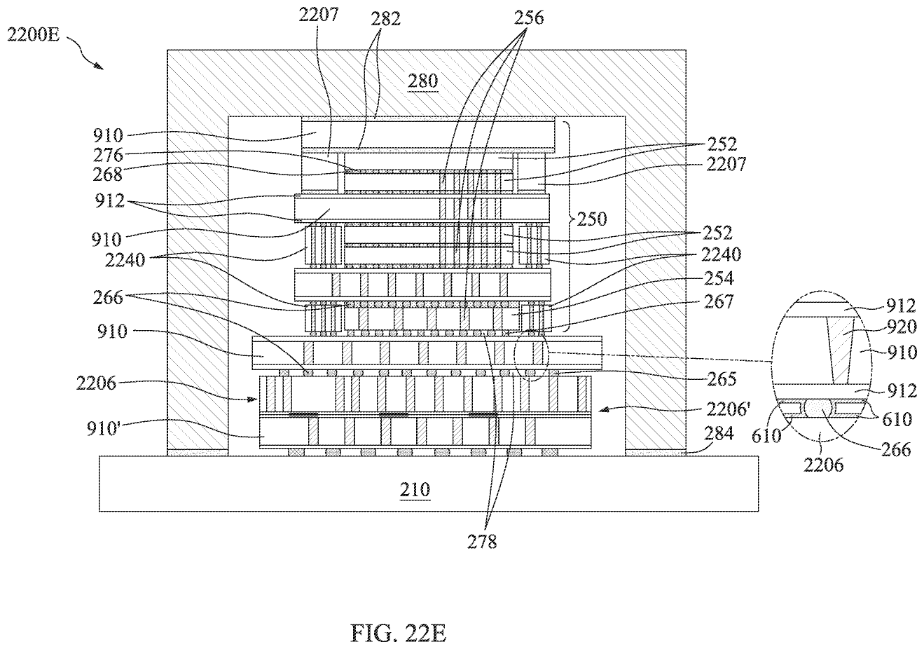

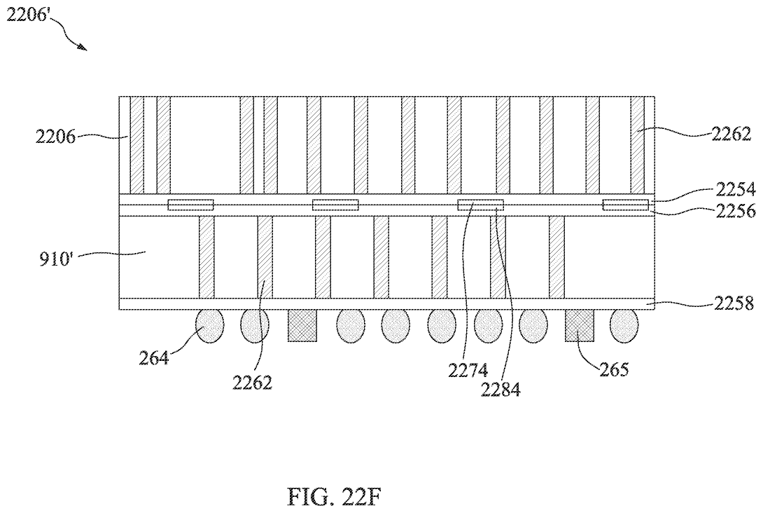

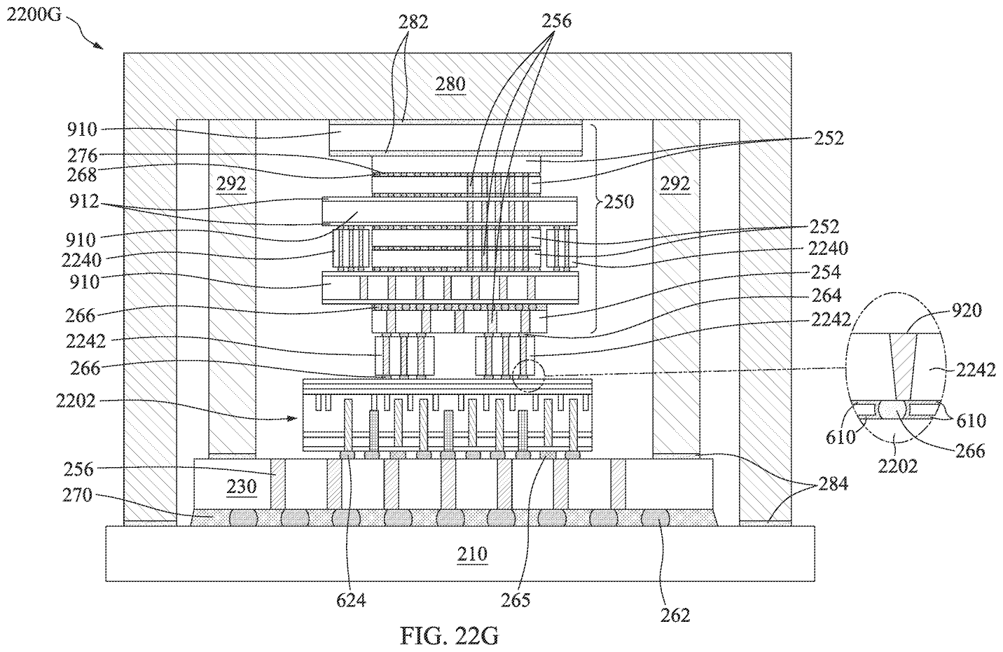

FIG. 9B shows a cross-sectional views of a semiconductor package 900B, in accordance with some embodiments of the present disclosure. The semiconductor package 900B is similar to the semiconductor package 900A, and similar features are not repeated for brevity. The main difference between the semiconductor package 900A and the semiconductor package 900B is the processor die 240 is replaced with a processor-HTC (high-thermal conductivity) heat spreader combo 930. The processor-HTC heat spreader combo 930 in FIG. 9B can be built based on a pre-fabricated composite substrate containing a semiconductor layer and a bulk HTC layer with a thickness of preferably 10 μm or higher a as opposed to silicon or a semiconductor substrate shown in FIG. 9A. The processor die 240 and the heat spreader 910 may also be manufactured and bonded together with a wafer-level bonding operation, and diced into the individual processor-HTC heat spreader combo 930. According to some embodiments, the processor die 240 and the heat spreader 910 in the same processor-HTC heat spreader combo 930 have substantially equal widths. The processor die 240 may be bonded to the heat spreader 910 through hybrid bonding using respective bonding layers on the facing sides of the processor die 240 and the heat spreader 910. According to some embodiments, the heat spreader 910 include interconnect structures or RDLs (not separately shown in FIG. 9B, but illustrated in FIG. 22A by labels 912) on its upper and lower sides for electrically connecting to the overlying and underlying features. Further, the conformal coating 610 is deposited on all the expose surfaces, e.g., the side surfaces of the processor-HTC heat spreader combo 930, including the side surfaces of the processor die 240 and the heat spreader 910, as illustrated in an enlarged view of the selected portion of the processor-HTC heat spreader combo 930 on the right side of FIG. 9B.

In order to improve heat dissipation efficiency of the liquid coolant for liquid immersion cooling of the semiconductor packages, 900A and 900B, an encapsulation material such as a NCP, an underfill or a molding compound can be seen absent in these packages in the spaces surrounding connectors 264 and 266. The resultant semiconductor package structure in the absence of the NCP or underfill may be more prone to damage due to insufficient structural rigidity against thermal expansion mismatch stresses incurred during field operation. The stresses caused by the CTE mismatch are the largest at the edges of the first substrate 210, the second substrate 230, the interposer 230 and the processor die 240 since the distances between these substrate/die edges to the neutral (central) points of the substrate/die are the greatest among the bond locations of the substrate/die. To address these concerns, enhancing structures, 265 and 267, for use with the first substrate 210, the interposer 230 and the processor die 240 are proposed as in the cases of semiconductor packages shown in FIGS. 6A to 8B.

FIGS. 10A to 10D show cross-sectional views of four different low-CTE, high-TC adjusters 1014, in accordance with various embodiments of the present disclosure. The CTE adjusters 1014 may be coupled to a substrate 1010, in which the substrate 1010 can be a substrate (e.g., the second substrate 220), the interposer 230 or a die shown in the previous embodiments. The CTE adjuster 1014 can be a (low-CTE, high-TC) stiffener formed on a periphery region over the substrate 1010 as shown in FIG. 10A, a stiffener formed on a sidewall of, or laterally surround, the substrate 1010 as shown in FIG. 10B, a stiffener embedded within the substrate 1010 as shown in FIG. 10C, a stiffener formed on a backside of the substrate 1010 as shown in FIG. 10D or a combination thereof, where the connectors 1016 reside on the backside of the substrate 1010 opposite to a front side of the substrate 1010 facing, for instance, the interposer 230. According to some embodiments, the CTE adjusters 1014 can adopt a ring shape from a top-view perspective.

The substrate 1010 may be an organic laminate substrate. According to some embodiments, the CTE adjusters 1014 have a CTE lower than a CTE of the substrate 1010. According to some embodiments, the CTE adjusters 1014 have a TC greater than a TC of the substrate 1010. As a result, the stresses of the bonding bumps between the substrate 1010 and its overlying structures, especially those on the edges of the substrate 1010, caused by thermal cycling incurred during device operation can be offset with the help of the CTE adjusters 1014 as shown in FIGS. 10A to 10D and combinations thereof. According to some embodiments, the CTE adjuster 1014 is referred to as one type of the enhancing structures.

The CTE adjusters 1014 can include diamond, graphene, boron nitride, boron arsenide, cubic boron arsenide, aluminum nitride, silicon carbide, copper-based material, a combination thereof, or the like. According to some embodiments, the CTE adjusters 1014 can include ceramics such as zirconia (with a CTE of about 10 ppm/° C.), alumina (with a CTE of about 6.5 ppm/° C.), cordierite (with a CTE of about less than 3 ppm/° C.) and aluminum nitride (with a CTE of about 5 ppm/° C.). In contrast to most ceramics, AlN has one of the highest thermal conductivity (TC) values in the group of ceramics, surpassed only by beryllium oxide. For mono-crystalline AlN, the TC value can reach as high as 285 W/(m·K) versus 150 W/(m·K) for silicon. For a polycrystalline AlN material, the TC value may be in the range of 70-210 W/(m. K).

The CTE adjusters 1014 may alternatively be formed of clad metals, e.g., Cu-Invar-Cu or Cu—Mo—Cu. Although AlN and other low-CTE and high-TC materials can be considered, clad metals such as copper-invar-copper (Cu-Invar-Cu) or copper-molybdenum-copper (Cu—Mo—Cu) can also be considered as a low-CTE, high-TC material. Invar is a Fe—Ni (iron-nickel) alloy with a 36% nickel content that exhibits the lowest CTE of known metals and alloys. For example, the CTE of the Invar is about 1.2 ppm/° C. between 20° and 100° C., and such CTE stays low from the lowest temperatures up to approximately 230° C. By adjusting the thicknesses of the first copper layer, the core metal (Invar or Mo) and the second copper layer, one can acquire the clad metal with a CTE close to that of silicon (about 3 ppm/° C.), or between that of silicon and that of laminate substrate (about 16-18 ppm/° C.). An invar sheet having a thickness of between 0.5 mil and 5 mil, and a layer of electrodeposited copper on at least one side of a thickness between 1 μm and 50 μm can have a CTE of about 2.8 to 6 ppm/° C. at a temperature between 0 and 200° F. In addition, one can adjust the thicknesses of the clad metal layers to achieve a high TC, e.g., 200-300 W/(m·K) in contrast to that of 400 W/(m·K) for copper, which is much higher than that of silicon (150 W/(m·K)).

According to some embodiments, a CTE adjuster 1014 can be bonded to the substrate 1010 through an adhesive 1012. The adhesive couples the CTE adjuster 1014 to the substrate 1010 thermo-mechanically. The adhesive 1012 that can be used includes a dielectric material, a polymeric material, a metal, or a material similar to those used in forming TIMs.

According to some embodiments, the coating 610 (not shown in FIGS. 10A to 10D) is coated on all the exposed surfaces of the semiconductor packages covering the substrate 1010, the CTE adjuster 1014 and/or the connectors 1016 following package assembly.

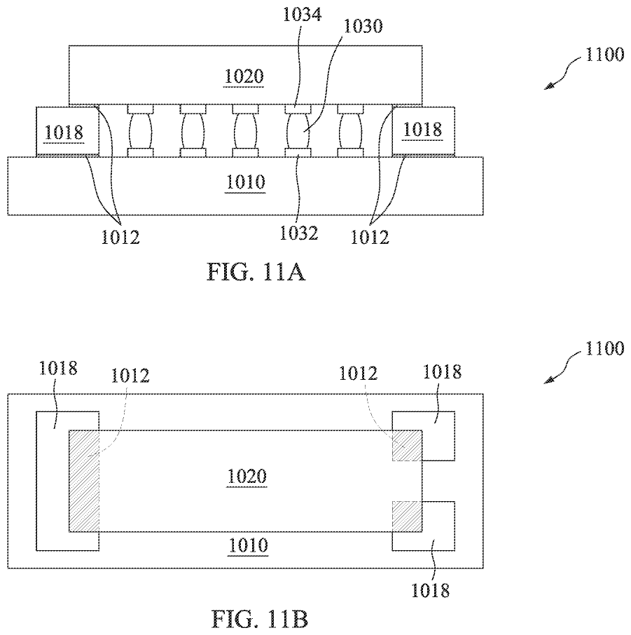

FIGS. 11A and 11B show a cross-sectional view and a top view, respectively, of a semiconductor structure 1100 with an enhancing structure 1018, in accordance with some embodiments of the present disclosure. According to some embodiments, the semiconductor structure 1100 shows a portion of a semiconductor package, e.g., one of the semiconductor packages illustrated in FIGS. 6, 7A, 7B, 8A, 8B, 9A and 9B. The semiconductor structure 1100 may include a lower substrate 1010, which corresponds to the second substrate 220, and an upper substrate 1020, which corresponds to the interposer 230, the processor die 240, or the like, and a plurality of connectors 1030, which correspond to the connectors 264 or 266.

Referring to FIG. 11A, according to some embodiments, and although not separately shown, the connectors, 264 and 266 of the embodiments with reference to FIGS. 6, 7A, 7B, 8A, 8B, 9A and 9B, include bonding pads 1032 on the upper surface of the lower substrate 1010, bonding pads 1034 on the lower surface of the upper substrate 1020 and bonding bumps 1030 for electrically connecting the corresponding bonding pads, 1032 and 1034. Each of the bonding pads 1032 is aligned with a corresponding bonding pad 1034 and bonded to the corresponding bonding pad 1034 through a corresponding bonding bump 1030.

According to some embodiments, since the spaces between the bonding bumps 1030 are not filled by an encapsulation material or dielectric layer (e.g., a NCP or an underfill), an enhancing structure 1018 is introduced to the edges of the lower substrate 1010 or the upper substrate 1020 to help control structure deformation caused by the CTE mismatch between the lower substrate 1010 and the upper structure 1020. The enhancing structure 1018 can be joined or bonded to the lower substrate 1010 and the upper substrate 1020 through an adhesive 1012. As shown in FIGS. 11A and 11B, the enhancing structure 1018 may extend along one side of the upper substrate 1020, or cover one or more corners, e.g., the four corners, of the upper substrate 1020 from a top-view perspective. According to some embodiments, the enhancing structure 1018 assumes a bar shape, a strip shape, or a pad shape from a top-view perspective. The enhancing structure 1018 can also serve as spacer between the lower substrate 1010 and the upper substrate 1020 to help ensure uniform joint heights between 1010 and 1020.

According to some embodiments, the enhancing structures 1018 can comprise a material or materials similar to those used in forming the CTE adjusters 1014. According to some other embodiments, the enhancing structures 1018 are formed of a NCP, an underfill, or an elastomer material. The adhesive 1012 can be based on materials with functions similar to those of the adhesive 1012 used in forming the structures shown in FIGS. 10A-10D. According to some embodiments, the enhancing structure 1018 is also referred to as one type of the enhancing structures.

According to some embodiments, the conformal coating 610 (not shown in FIGS. 11A and 11B) is coated on all the exposed surfaces of the lower substrate 1010, the upper substrate 1020, the enhancing structure 1018, the adhesive 1012, bonding bumps 1030, and the bonding pads 1032, 1034 following package assembly.

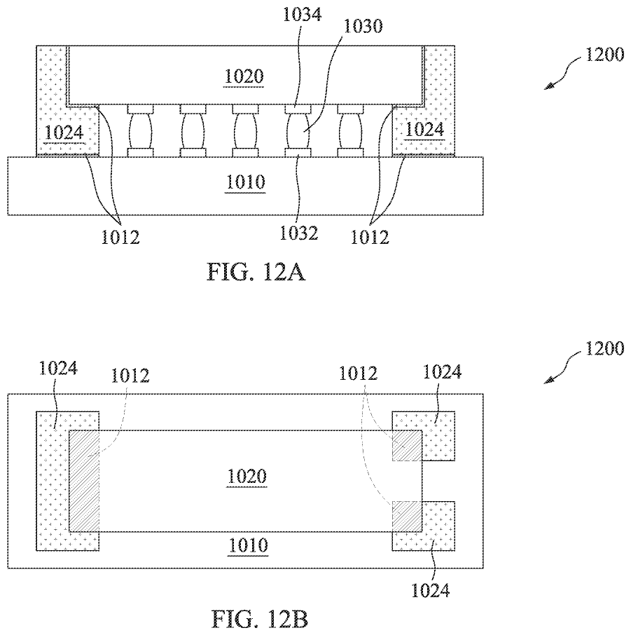

FIGS. 12A and 12B show a cross-sectional view and a top view, respectively, of a semiconductor structure 1200 with an enhancing structure 1024, in accordance with some embodiments of the present disclosure. The enhancing structure 1024 are in many ways similar to the enhancing structures 1018, and similar features are not repeated for brevity. According to some embodiments, the enhancing structures 1024 can be made based on a material similar to that used in making the enhancing structures 1018. The main difference between the enhancing structures 1024 and the enhancing structures 1018 is the enhancing structure 1024 extends to cover at least part of the sidewalls of the upper substrate 1020, or laterally surround the upper substrate 1020, as illustrated in FIG. 12A. As a result, the adhesive 1012 also extend to cover the sidewalls of the upper substrate 1020. The greater coverage area of the enhancing structure 1024 can provide greater extent of reinforcement to the lower substrate 1010 and the upper substrate 1020 in the face of thermal cycling induced thermal expansion mismatch stresses.

According to some embodiments, the coating 610 (not shown in FIGS. 12A and 12B) is coated on the exposed surfaces of the lower substrate 1010, the upper substrate 1020, the enhancing structure 1024, the adhesive 1012, bonding bumps 1030, and the bonding pads, 1032 and 1034, following package assembly.

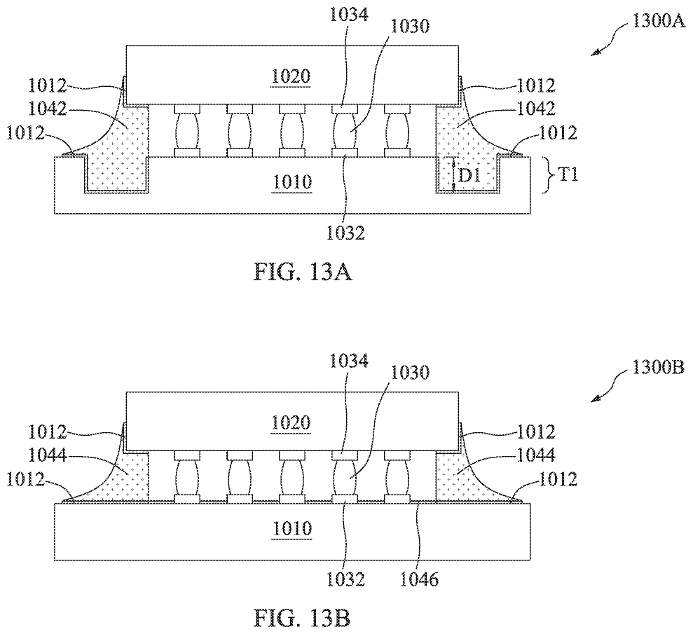

FIG. 13A shows a cross-sectional view of a semiconductor structure 1300A with an enhancing structure 1042, in accordance with some embodiments of the present disclosure. The enhancing structure 1042 is in many aspects similar to the enhancing structures 1018 and 1024, and similar features are not repeated for brevity. According to some embodiments, the enhancing structures 1042 can be made of a material similar to that used in forming the enhancing structures 1018 or 1024. The main difference between the enhancing structures 1042 and the enhancing structures 1018 or 1024 is the enhancing structure 1042 extends to the corners of the upper substrate 1020, or is entrenched in the lower substrate 1010, as illustrated in FIG. 13A. The enhancing structure 1042 may also form a tapered shape from the lower substrate 1010 to the upper substrate 1020. According to some embodiments, the enhancing structures 1042 extend to cover at least portions of the sidewalls of the upper substrate 1020, or at least laterally and partially surround the upper substrate 1020. As a result, the adhesive 1012 also extends to cover the sidewalls of the upper substrate 1020. In the structures shown in FIGS. 11A to 12B, the adhesive 1012 may be omitted if the starting materials of the enhancing structures are themselves adhesives.

According to some embodiments, as seen in FIG. 13A, the lower substrate 1010 includes one or more trench T1 exposed from the upper surface of the lower substrate 1010. The trench T1 may assume a ring shape, a bar shape, a strip shape or a pad shape. The trench T1 may be distributed near the edges or corners of the lower substrate 1010. The enhancing structures 1042 may extend to a depth D1 of the lower substrate 1010. Thus, the enhancing structures 1042 extend to the trench T1 and fill the trench T1. The enhancing structures 1042 may therefore extend into the lower substrate 1010 with a thickness D1. The greater coverage area of and extension into the lower substrate 1010 by the enhancing structure 1042 may provide greater reinforcement function to the lower substrate 1010 and the upper substrate 1020. The upper substrate 1020 or the lower substrate 1010 can therefore be kept from severe deformation due to the CTE mismatch during device operation.

FIG. 13B shows a cross-sectional view of a semiconductor structure 1300B with an enhancing structure 1044, in accordance with some embodiments of the present disclosure. The enhancing structure 1044 is in many aspects similar to the enhancing structures 1042, and similar features are not repeated for brevity. The main difference between the enhancing structures 1044 and 1042 is the absence of the trench T1 from the lower substrate 1010, as illustrated in FIG. 13B. The arrangement of removing the trench T1 from the lower substrate 1010 may be suitable for thin substrates, or substrates that do not have sufficient spaces for the trench T1.

According to some embodiments, the semiconductor structure 1300B includes a non-wetting layer 1046 formed on the upper surface of the lower substrate 1010. The non-wetting layer 1046 can be formed on the upper surface of the lower substrate 1010 between the enhancing structures 1044 and between the bonding pads 1032. According to some embodiments, the non-wetting layer 1046 is formed of a material such as polytetrafluoroethylene, PTFE or the like. The non-wetting layer 1046 prevents wetting of the enhancing structure material 1044 during its application in the form of a liquid adhesive.

According to some embodiments, the coating 610 (not shown in FIGS. 13A and 13B) is coated on the exposed surfaces of the lower substrate 1010, the upper substrate 1020, the enhancing structure 1044, the adhesive 1012, bonding bumps 1030, and the bonding pads 1032, 1034 following package assembly.

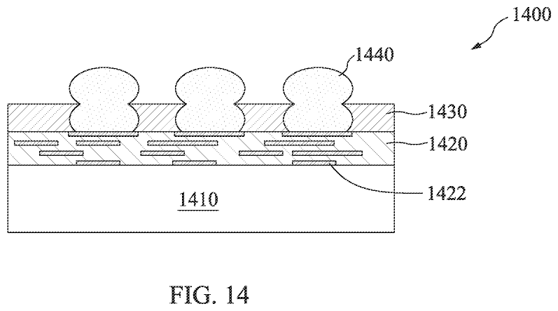

FIG. 14 shows a cross-sectional view of a semiconductor structure 1400 with an enhancing structure 1430, in accordance with some embodiments of the present disclosure. The semiconductor structure 1400 includes a substrate 1410, an interconnect structure 1420, an enhancing structure 1430, and a plurality of connectors 1440. According to some embodiments, the substrate 1410 can be the second substrate 220, the interposer 230 or the processor die 240 shown in the previous embodiments. The interconnect structure 1420, also referred to as redistribution layers (RDL), includes a plurality of metallization layers. Each of the metallization layers includes a plurality of metal wiring (an exemplary metal wiring 1422 is shown in FIG. 14). The metallization layers also include a plurality of metal vias (not separately shown) to connect the underlying metal lines to corresponding overlying metal lines. The interconnected metal lines and metal vias form one or more conduction paths to electrically connect the components mounted on the substrate 1410 through the connectors 1440. According to some embodiments, the connectors 1440 correspond to the connectors 262, 264, 266 or 268 of the preceding embodiments.

According to some embodiments, the enhancing structure 1430 is arranged over the interconnect structure 1420. The enhancing structure 1430 may laterally surround lower portions of the connectors 1440 to protect the connectors 1440 from cracking or unintentional bridging. Therefore, the enhancing structure 1430 is also referred to as a stress compensation layer. The enhancing structure 1430 may include a dielectric material such as silicon dioxide, silicon nitride, silicon oxynitride, silicon carbide, a polymeric material, an underfill material, a combination thereof, or the like. The enhancing structure 1430 may also be formed of a photoresist material. The enhancing structure 1430 may be formed over the interconnect structure 1420 by chemical vapor deposition (CVD), physical vapor deposition (PVD), atomic layer deposition (ALD), spin coating, or other suitable deposition methods.

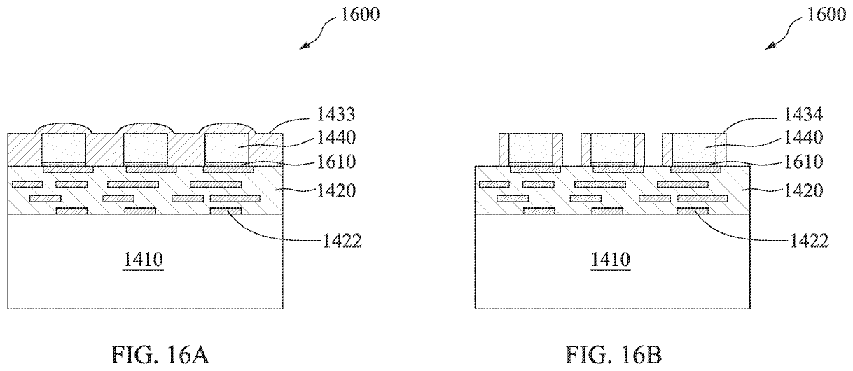

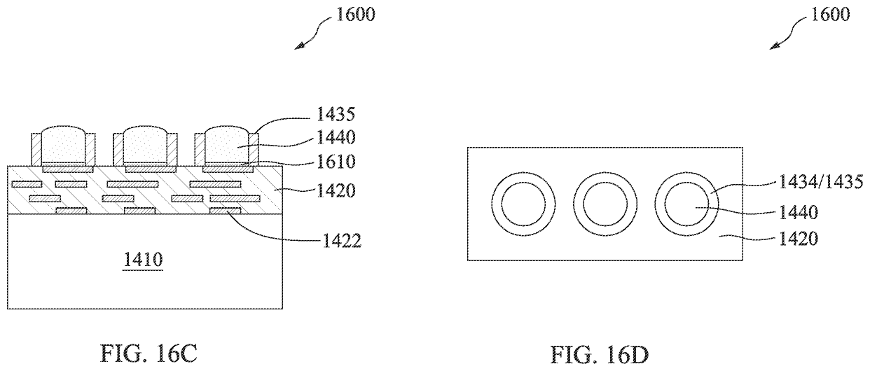

The semiconductor structure 1400 may further alternatively or additionally include a under bump metallization (UBM) layer 1610 (shown in FIGS. 16A˜16B, not separately shown in FIG. 14, but illustrated in FIGS. 16A to 16C as feature 1610) between each connector 1440 and the interconnect structure 1420. In this case, the enhancing structure 1430 may laterally surround the UBM layers to support and protect the UBM layers from stress-induced cracking. According to some embodiments, the coating 610 (not shown in FIG. 14) is coated on the exposed surfaces of the substrate 1410, the interconnect structure 1420, the enhancing structure 1430, the connectors 1440, and the UBM layer after package assembly.

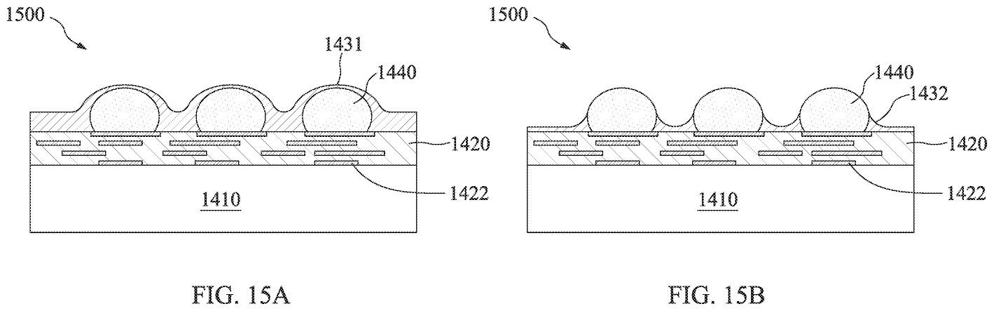

FIGS. 15A and 15B shows cross-sectional views of intermediate stages of forming a semiconductor structure 1500 with an enhancing structure 1432, in accordance with some embodiments of the present disclosure. The semiconductor structure 1500 is similar to the semiconductor structure 1400, and similar features are not repeated for brevity. Referring to FIG. 15A, a material 1431 of the enhancing structure 1432 (shown in FIG. 15B) is deposited over the interconnect layer 1420. The material 1431 may include a material identical to the stress compensation layer 1430 shown in FIG. 14. The material 1431 may be formed over the interconnect layer 1420 by spin coating, or other suitable deposition methods. As a result, the material 1431 may cover the surface of the interconnect structure 1420 as well as the entirety of the connectors 1440.

Referring to FIG. 15B, a thermal operation is performed on the semiconductor structure 1500. According to some embodiments, the thermal operation includes a baking operation. The thermal operation may cause shrinkage of the material 1431, thereby exposing upper portions of the connectors 1440. The enhancing structure 1432 covers or laterally surrounds the lower (bottom) portions of the connectors 1440 and provides strengthening function to the connectors 1440 against thermal expansion mismatch stresses. Therefore, the resultant enhancing structure 1432 may also be referred to as a stress compensation layer.

According to some embodiments, the coating 610 (not shown in FIGS. 15A and 15B) is coated on the exposed surfaces of the substrate 1410, the interconnect structure 1420, the enhancing structure 1432 and the connectors 1440 following package assembly.

FIGS. 16A to 16C shows cross-sectional views of intermediate stages of forming a semiconductor structure 1600 with an enhancing structure 1435, in accordance with some embodiments of the present disclosure. The semiconductor structure 1600 is similar to the semiconductor structure 1400 or 1500, and similar features are not repeated for brevity. Referring to FIG. 16A, an under bump metallization (UBM) layer 1610 is formed between the interconnect layer 1420 and a corresponding connector 1440 to support the connectors 1440 and electrically couple the interconnect layer 1420 to the connector 1440. The UBM layer 1610 may be formed of one or more metallic materials, e.g., titanium, titanium-tungsten, copper, nickel, or the like. Further a material 1433 of the enhancing structure 1435 (shown in FIGS. 16C and 16D) is deposited over the interconnect layer 1420. The material 1433 may include a material identical to that in forming the stress compensation layer 1430 or 1431 shown in FIG. 14 or 15A. The material 1433 may be formed over the interconnect layer 1420 by spin coating or other suitable deposition methods. As a result, the material 1433 may cover the surface of the interconnect structure 1420 as well as the entirety of the connectors 1440.

Referring to FIG. 16B, a patterning operation is performed on the semiconductor structure 1600. According to some embodiments, the patterning operation includes photolithography and etching operations. The etching operations may include a dry etch, a wet etch, a reactive ion etch (RIE), or the like. Through the patterning operation, each of the connectors 1440 is laterally surrounded by a ring-shaped enhancing structure 1434. Each of the enhancing structures 1434 may be separated from each other and covers sidewalls of the respective connectors 1440. According to some embodiments, the upper surfaces of the connectors 1440 are level with the upper surfaces of the enhancing structures 1434 as shown in FIG. 16B. As illustrated in FIG. 16B, the enhancing structure 1434 forms a ring surrounding each respective connector 1440 from a top-view perspective.

Referring to FIG. 16C, a thermal operation is performed on the semiconductor structure 1600. The thermal operation may cause expansion of the connectors 1440, thereby leading to a protruding top portion of the connector 1440 and the resultant enhancing structure 1435 as shown in FIG. 16C. The protruding portion of the connectors 1440 allows for bonding the semiconductor structure 1600 to other structures. The enhancing structure 1435 covers or laterally surrounds the connectors 1440 and provides strengthening forces to the connectors 1440 against stresses. Therefore, the enhancing structure 1435 may also be referred to as a stress compensation layer.

According to some embodiments, the coating 610 (not shown in FIGS. 16A to 16D) is coated on the exposed surfaces of the substrate 1410, the interconnect structure 1420, the enhancing structure 1435, the connectors 1440 following package assembly.

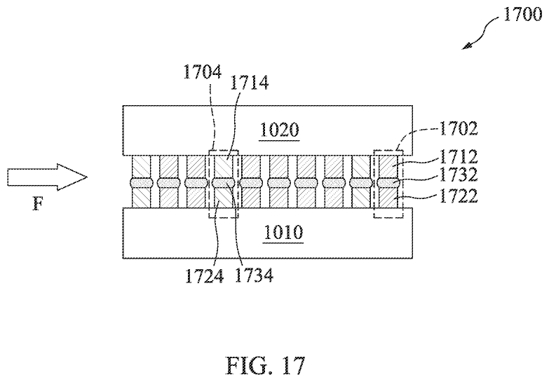

FIG. 17 shows a cross-sectional view of a semiconductor structure 1700 with an enhancing structure appearing as a dummy connector 1704, in accordance with some embodiments of the present disclosure. The semiconductor structure 1700 is similar to the semiconductor structure, 1100, 1200, 1300A or 1300B, in many aspects and similar features are not repeated for brevity. The main difference between the semiconductor structure 1700 and the semiconductor structure, 1100, 1200, 1300A or 1300B, is that the semiconductor structure 1700 includes both active connectors 1702 and dummy connectors 1704 joining the lower substrate 1010 to the upper substrate 1020. The active connectors 1702 may serve the functions of electrically connecting the lower substrate 1010 and the upper substrate 1020 as well as heat dissipation. The dummy connectors 1704 may not serve the function of electrically connecting the lower substrate 1010 and the upper substrate 1020, but may serve as the enhancing structure in the semiconductor structure 1700 to improve the structural integrity of the semiconductor structure 1700. Further, the dummy connectors 1704 can be placed close to chip hot spots of the lower substrate 1010 and/or the upper substrate 1020 to provide additional pathways heat dissipation from chip hot spots. Therefore, the dummy connectors 1704 are considered as one type of enhancing structure for strength and/or heat dissipation.

According to some embodiments, the active connectors 1702 each include a first conductive member 1712, a second conductive member 1722 and a third conductive member 1732 between the first conductive member 1712 and the second conductive member 1722. The first conductive member 1712 or the second conductive member 1722 may be a conductive pillar, a conductive via, or a conductive bump, and may be formed of metallic materials, e.g., tungsten, copper, silver, gold, aluminum, titanium, alloys or the like. According to some embodiments, the third conductive member 1732 is a conductive bump and is formed of a solder material. The third conductive member 1732 may also be formed of a soft metal, e.g., lead, gold, silver, tin, zinc, aluminum, thorium, copper, brass and bronze.

According to some embodiments, each of the dummy connectors 1704 includes a first conductive member 1714, a second conductive member 1724 and a third conductive member 1734 between the first conductive member 1714 and the second conductive member 1724. The first conductive member 1714 or the second conductive member 1724 may be a conductive pillar, a conductive via, or a conductive bump, and may be formed of metallic materials, e.g., tungsten, copper, silver, gold, aluminum, titanium, alloys thereof, of the like. According to some embodiments, the third conductive member 1734 is a conductive bump and is formed of a solder material. The third conductive member 1734 may also be formed of a soft metal, e.g., lead, gold, silver, tin, zinc, aluminum, thorium, copper, brass and bronze.

According to some embodiments, the active connectors 1702 and the dummy connectors 1704 have a greater length compared to existing connectors for conventional 2.5D ICs or 3D ICs. For example, the first conductive members, 1712 and 1714, or the second conductive members, 1722 and 1724, each has a length greater than a length of the third conductive members, 1732 and 1734. According to some embodiments, the first conductive members, 1712 and 1714, or the second conductive members, 1722 and 1724, each has a length substantially equal to or greater than twice or triple the length of the third conductive members, 1732 and 1734. The lengthened connectors 1702 and 1704 can aid in reducing the degree of deformation at the joints between the lower substrate 1010 and the upper substrate 1020 due to the CTE mismatch, especially for the edge regions of the substrates 1010 and 1020. Furthermore, the lengthened connectors, 1702 and 1704, enlarge the spaces between the lower substrate 1010 and the upper substrate 1020. The expanded spaces can allow more liquid coolant (whose flow direction is indicated by the arrow F) to flow through the semiconductor structure 1700 while being in close proximity to chip hot spots, thereby increasing the heat dissipation efficiency of the fluid coolant.

According to some embodiments, the coating 610 (not shown in FIG. 17) is coated on the exposed surfaces of the substrates 1010, 1020, the active connectors 1702, the dummy connectors 1704 following package assembly.

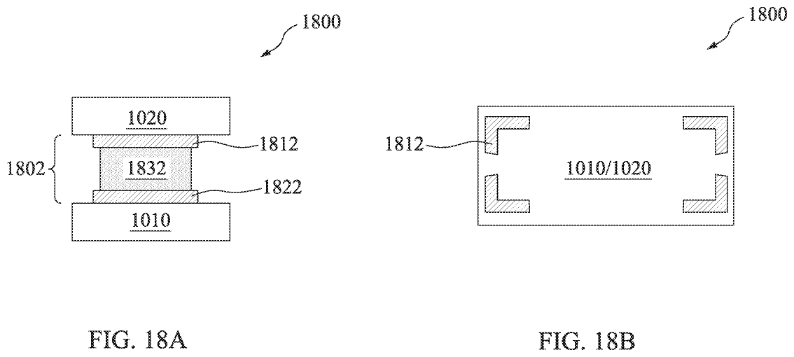

FIGS. 18A and 18B show a cross-sectional view and a top view, respectively, of a semiconductor structure 1800 with an enhancing structure 1802, in accordance with some embodiments of the present disclosure. The semiconductor structure 1800 is similar to the semiconductor structure 1700 in many aspects and similar features are not repeated for brevity. The main difference between the semiconductor structure 1800 and the semiconductor 1700 is that the semiconductor structure 1800 includes specially shaped connectors 1812 serving as the enhancing structure in the semiconductor structure 1800 for bonding the lower substrate 1010 to the upper substrate 1020. Referring to FIG. 18B, the “L” shaped connectors 1802 may be arranged near the corners of the lower substrate 1010 or the upper substrate 1020 to mitigate the stresses at the edges or corners of the lower substrate 1010 or the upper substrate 1020 due to the CTE mismatch. Besides the L shape, other shapes can also be devised per need.

According to some embodiments, the connector 1802 includes a first conductive member 1812, a second conductive member 1822 and a third conductive member 1832 between the first conductive member 1812 and the second conductive member 1822 as shown in FIG. 18A. The first conductive member 1812 or the second conductive member 1822 may be a conductive pad, a conductive pillar, a conductive via, or a conductive bump, and may be formed of metallic materials, e.g., tungsten, copper, silver, gold, aluminum, titanium, alloys thereof, of the like. According to some embodiments, the third conductive member 1832 is a conductive bump and can be formed of a solder material. The third conductive member 1832 may also be formed of a soft metal, e.g., lead, gold, silver, tin, zinc, aluminum, thorium, copper, brass and bronze.

According to some embodiments, the connectors 1802 assumes a L shape conformal to the corner shapes or the two joined sides of the lower substrate 1010 and the upper substrate 1020. Therefore, the components of the connector 1802, i.e., the first conductive member 1812, the second conductive member 1822 and the third conductive member 1832, may also have an L-shape conformal to the corner shapes or the two joined sides of the lower substrate 1010 and the upper substrate 1020. The extended area of the connectors 1802 may provide additional reinforcement function to compensate for the stresses at the joints around the corners of the lower substrate 1010 and the upper substrate 1020. According to some embodiments, the connectors 1802 are configured as dummy connectors. The L-shaped embodiment of the connector 1802 shown in FIG. 18B is provided for illustrative purposes. Other non-circular shapes from a top-view perspective, e.g., any irregular shape, for the connector 1802 may be within the contemplated scope of the present disclosure.

According to some embodiments, the coating 610 (not shown in FIGS. 18A and 18B) is coated on the exposed surfaces of the substrates 1010, 1020, and the connectors 1802 after the formation of the connectors 1802.

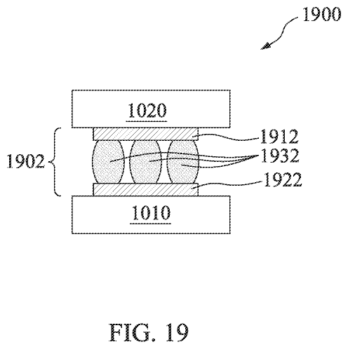

FIG. 19 shows a cross-sectional view of a semiconductor structure 1900 with an enhancing structure 1902, in accordance with some embodiments of the present disclosure. The semiconductor structure 1900 is similar to the semiconductor structure 1700 or 1800 in many aspects and similar features are not repeated for brevity. The main difference between the semiconductor structure 1900 and the semiconductor structure, 1700 or 1800, is that the semiconductor structure 1900 includes a plurality of connectors per bond or per joint 1902 serving as the enhancing structure in the semiconductor structure 1900 that bonds the lower substrate 1010 to the upper substrate 1020.

According to some embodiments, each connector 1902 includes one first conductive member 1912, one second conductive member 1922 and a plurality of third conductive members 1932 proximal to the first conductive member 1912 and the second conductive member 1922. The first conductive member 1912 or the second conductive member 1922 may be a conductive pad, a conductive pillar, a conductive via, or a conductive bump, and may be formed of metallic materials, e.g., copper, tungsten, silver, gold, aluminum, titanium, alloys thereof, of the like. According to some embodiments, the third conductive members 1932 is a conductive bump and is formed of a solder material. The first conductive member 1912, the second conductive member 1922 and third conductive members 1932 may also be formed of a soft metal, e.g., lead, gold, silver, tin, zinc, aluminum, thorium, copper, brass and bronze.

According to some embodiments, the plurality of third conductive members 1932 are separated from each other, thereby creating spaces or gaps 278 similar to the gaps 278 shown in FIGS. 6, 7A, 8A, 8B, 9A and 9B. The gaps 278 allows for more liquid coolant to pass through the semiconductor structure 1900 and enhance heat dissipation efficiency.

According to some embodiments, the coating 610 (not shown in FIG. 19) is coated on the exposed surfaces of the substrates 1010, 1020, and the connectors 1902 following package assembly.

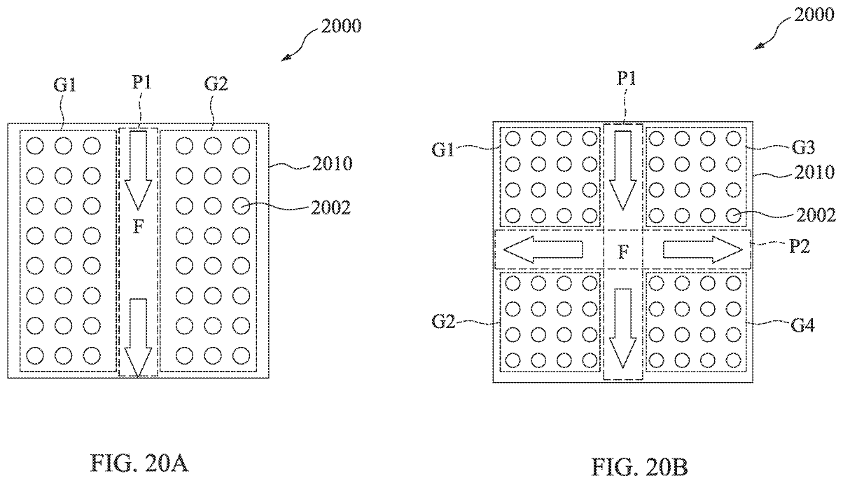

FIGS. 20A and 20B show top views of a substrate 2010 with a heat dissipation enhancing structure, in accordance with various embodiments of the present disclosure. The substrate 2010 may be the second substrate 220, the interposer 230, the processor die 240, the lower substrate 1010 or the upper substrate 1020 of the preceding embodiments. Referring to FIG. 20A, the substrate 2010 includes an array of connectors 2002 formed on an upper surface of the substrate 2010. The array of connectors 2002 is partitioned into a first group G1 and a second group G2, wherein the first group G1 and the second group G2 are separated by a passage P1 where no connectors are formed. According to some embodiments, the layout of the connectors 2002 form a strip-shaped or bar-shaped heat dissipation enhancing structure, where a pitch of the connectors 2002 within the first group G1 or within the second group G2 is less than a pitch between the two groups, e.g., G1 and G2. The passage P1 may allow the liquid coolant (indicated by the arrow F) to pass over the surface of the substrate 2010 proximal to chip hot spots with less resistance, thereby increasing the heat dissipation efficiency.

Referring to FIG. 20B, the substrate 2010 includes an array of connectors 2002 formed on an upper surface of the substrate 2010. The array of connectors 2002 is partitioned into four groups G1, G2, G3 and G4, wherein the groups, G1, G2, G3 and G4, are separated from each other by the two passages, P1 and P2 whereupon no connectors are formed. According to some embodiments, the layout of the connectors 2002 form a cross-shaped heat dissipation enhancing structure defined by the passages P1 and P2, where a pitch of the connectors 2012 within each of the groups, G1 to G4, is less than a pitch between any two adjacent groups, e.g., G1 and G2 or G1 and G3. The passage P1 or P2 may allow the liquid coolant (indicated by the arrow F) to pass over the surface of the substrate 2010 proximal to chip hot spots with less resistance, thereby increasing the heat dissipation efficiency.

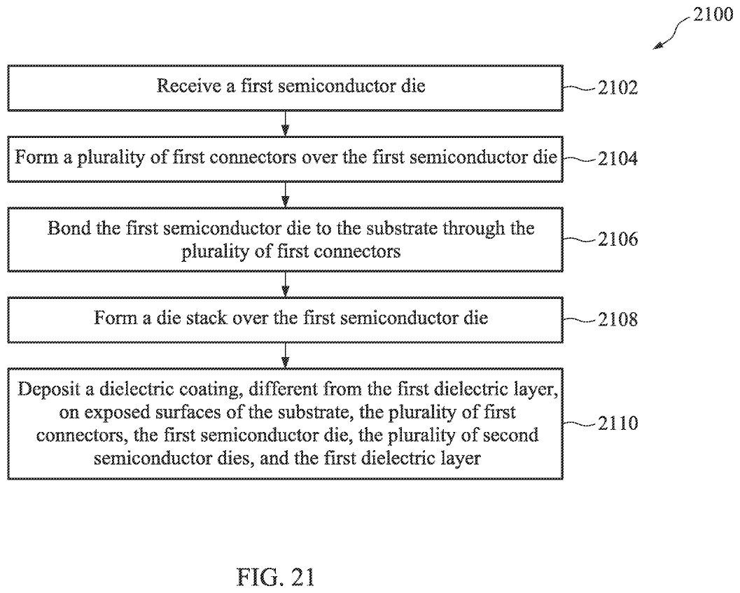

FIG. 21 shows a schematic flow chart of a method 2100 of manufacturing a semiconductor package, in accordance with some embodiments of the present disclosure. It shall be understood that additional steps can be provided before, during, and after the steps in method 2100, and some of the steps described below can be replaced with other embodiments or eliminated. The order of the steps shown in FIG. 21 may be interchangeable. Some of the steps may be performed concurrently or independently.

At step 2102, a first semiconductor die, e.g., the processor die 240 or the interposer 230, is received or formed. The first semiconductor die may subsequently be bonded to a substrate, e.g., the first substrate 210 or the second substrate 220.

At step 2104, a plurality of first connectors, e.g., connectors 264 or 266, are formed over the first semiconductor die. At step 2106, the first semiconductor die is bonded to the substrate through the plurality of first connectors.

At step 2108, a die stack, e.g., the die stack 250, is formed or mounted over the first semiconductor die. The die stack may include at least one control die, e.g., the control die 254, and a plurality of memory dies, e.g., memory dies 252, in a stack. The die stack may also include connectors, e.g., connectors 266 or 268, arranged between and electrically connecting the adjacent memory dies or between the bottommost memory die 252 and the control die 254. The die stack may be encapsulated with, for instance, a molding compound following die/wafer assembly. According to some embodiments, a first dielectric layer, e.g., the dielectric layer 276 encapsulates the plurality of second connectors.

At step 2110, a dielectric coating, e.g., the conformal coating 610, that is different from the first dielectric layer, is deposited on the exposed surfaces of the substrate, the plurality of first connectors, the first semiconductor die, the plurality of second semiconductor dies, the first dielectric layer and all other exposed surfaces.

FIG. 22A shows a cross-sectional view of a semiconductor package 2200A, in accordance with some embodiments of the present disclosure. The semiconductor package 2200A is similar to the semiconductor package 900A shown in FIG. 9A, and similar features are not repeated for brevity. The main difference between the semiconductor packages 2200A and 900A is that the processor die 240 of the semiconductor package 900A is replaced with a processor die 2202 in FIG. 22A. The processor die 2202 is electrically bonded to the interposer 230 and an overlying interposer 910 through connectors 264 and 266, respectively. Furthermore, the exposed surfaces of the processor die 2202 are coated with the coating 610, as illustrated by an enlarged portion of the semiconductor package 2200A shown on the right side of FIG. 22A.

FIG. 22B shows a cross-sectional view of the processor die 2202 in the semiconductor package 2200A shown in FIG. 22A, in accordance with some embodiments of the present disclosure. The processor die 2202 includes a first interconnect structure 2210, a second interconnect structure 2216, a third interconnect structure 2218, a first substrate 2220, a second substrate 2226, a fourth interconnect structure 2224, and a fifth interconnect structure 2228. Further, the processor die 2202 includes a plurality of conductive vias 2232, a plurality of conductive vias 2234, a plurality of conductive vias 2236 and a plurality of conductive vias 2238.

The first substrate 2220 may be formed of a semiconductor material, e.g., silicon, silicon carbide, silicon germanium, silicon-on-insulator, or other suitable materials. According to some embodiments, the first substrate 2220 serves as a circuit layer and includes one or more electrical components, e.g., transistors, capacitors, inductors, resistors, diodes, and the like. The first substrate 2220 may serve the function of the processor die 240 in the previous embodiments. The first interconnect structure 2210, which in some embodiments can be a local interconnect in a back-end-of-line (BEOL) structure, is formed over the first substrate 2220 and configured to interconnect the electrical components of the first substrate 2220 and route the circuitry of the first substrate 2220 to the overlying second interconnect structure 2216 and the third interconnect structure 2218 on top of the second interconnect structure 2216. The second interconnect structure 2216 can be an intermediate interconnect in a BEOL structure while the third interconnect structure 2218 can be a redistribution layer (RDL). According to some embodiments and referring to FIGS. 22A and 22B, the second interconnect structure 2216 is configured to electrically connect the first substrate 2220 through the first interconnect structure 2210.

According to some embodiments, the second substrate 2226 is a semiconductor substrate that can be formed from a semiconductor material such as silicon, silicon carbide, silicon germanium, silicon-on-insulator, or other suitable materials. In the depicted example, the second substrate 2226 is a silicon substrate.

According to some embodiments, the second substrate 2226 can be formed of a low-CTE, high-TC dielectric material such as diamond, boron nitride, aluminum nitride, silicon carbide, silicon, a composite material comprising a semiconductor layer and a low-CTE, high-TC layer or a combination thereof.

Conductive vias, 2232 and 2234, are formed through the first substrate 2220 while conductive vias, 2236 and 2238, are formed in both the first substrate 2220 and the second substrate 2226. The conductive vias may be formed of a conductive material, such as copper, tungsten, aluminum, gold, cobalt, ruthenium, molybdenum, palladium, platinum, rhodium, iridium, osmium, a combination thereof, or the like in combination of suitable passivation/adhesion/barrier layers. According to some embodiments, the conductive vias can serve as thermal vias for heat dissipation. According to some other embodiments, the conductive vias can serve as electrically conductive vias. Conductive vias 2236 can be created close to the front-end-of-line (FEOL) electrical components of the first substrate 2220 and chip hot spots of the semiconductor package 2200A for improving the heat dissipation efficiency.

The fourth interconnect structure 2224, which can be a combination of a global interconnect in a BEOL structure deposited on the backside of the first substrate 2220 and/or a RDL structure on the first substrate 2220 and/or the second substrate 2226 connecting the two substrates using copper hybrid bonding. The corresponding hybrid bonding layers are omitted in FIG. 22B for brevity. The fourth interconnect structure 2224 may be configured to interconnect the electrical components of the first substrate 2220, and route the circuitry of the first substrate 2220 to the underlying fifth interconnect structure 2228 through the second substrate 2226. According to some embodiments and referring to FIGS. 22A and 22B, the fifth interconnect structure 2228 is configured to electrically connect the fourth interconnect structure 2224 to the underlying connectors 264.

The conductive vias 2236 which are formed in the first substrate 2220 and the second substrate 2226 and extend through the second substrate 2226 are connected to the fourth interconnect structure 2224 and the fifth interconnect structure 2228. The conductive vias 2238 which are formed through the second substrate 2226, and are connected to the fourth interconnect structure 2224 and the fifth interconnect structure 2228 can be electrically connected to conductive vias 2234. The conductive vias, 2236 or 2238, may be formed of a conductive material such as copper, tungsten, aluminum, gold, cobalt, ruthenium, molybdenum, palladium, platinum, rhodium, iridium, osmium, a combination thereof, or the like in combination of suitable passivation/adhesion/barrier layers. According to some embodiments, the conductive vias 2236 serve as thermal vias and are thermally, instead of electrically, connected to the first substrate 2220. According to some embodiments, the conductive vias 2238 serve as active conductive vias electrically connected to the first substrate 2220. The conductive vias 2236 can be arranged close to the electrical components of the first substrate 2220 that are identified as hot spots of the semiconductor package 2200A for improving the heat dissipation efficiency.

According to some embodiments, the conductive vias, 2234 and 2238, may be configured to provide power to the first substrate 2220 through a backside (i.e., the second substrate side) of the processor die 2202, and therefore the conductive vias, 2234 and 2238, and the fourth and fifth interconnect structures, 2224 and 2228, may be referred to as a backside power delivery network (BSPDN). The conductive via 2234 may be used in conjunction with buried power rail for transmitting power transmission from the backside. The BSPDN may provide more opportunities of power connections for the semiconductor package 2200A from the backside of the semiconductor package 2200A in addition to the front side of the semiconductor package 2200A. The device footprint and power consumption can therefore be substantially reduced with BSPDN versus the traditional IC design which up until now is relying on front-side power delivery network (FSPDN) with power delivery and signaling done at the chip's circuit side. BSPDN is one of the key technologies to enable scaling of future chips below 3 nm and the migration from finFET to nano-sheet transistors. BSPDN allows designers to decouple the power delivery network from the signal network on the IC front-side, i.e., the BEOL (back-end-of-line) side. For future advanced ICs, the advantages of BSPDN include enhanced signal integrity, reduced IR drop, improved power delivery performance, reduced BEOL routing congestion, as well as further standard cell scaling. An ideal BSPDN has to deliver constant, stable supply voltage to active circuits on the IC during any activity. A key parameter here is the DC resistance of the power delivery network in all the interconnect paths, from the IC's power supply pins to the transistors in the IC.

According to some embodiments, referring to FIG. 22A, at least one of the heat interposers 910 includes top and bottom interconnect structures 912 (e.g., RDLs) arranged on a top level and a bottom level of the respective heat spreader 910. The top or bottom interconnect structure 912 may help route the circuitry in the overlying (underlying) layer to the underlying (overlying) layer using through vias 920 in addition to the functions of dissipation heat through these through vias 920.

The interconnect structures and conductive vias of the semiconductor package 2200A shown in FIGS. 22A and 22B are provided for illustrative purposes. Other device and interconnect structure combinations are also within the contemplated scope of the present disclosure.

According to some embodiments, the exposed surfaces of the processor die 2202, e.g., the third interconnect structure 2218, or the sidewall of the processor die 2202, the exposed surfaces of the interposer 230, the exposed surfaces of the memory dies 252, the exposed surfaces of the control die 254, the exposed surfaces of the heat spreader 280 are deposited with the coating 610, as illustrated by an enlarged portion of the semiconductor package 2200A shown on the right side of FIG. 22A. The same arrangement of the coating 610 also applies to other embodiments described herein.

FIG. 22C shows a cross-sectional view of a semiconductor package 2200C, in accordance with some embodiments of the present disclosure. The semiconductor package 2200C is similar to the semiconductor package 2200A, and similar features are not repeated for brevity. The main difference between the semiconductor packages 2200A and 2200C is that the processor die 2202 is replaced with a processor die 2204. The processor die 2204 is different from the processor die 2202 mainly in that the processor die 2204 presented in FIG. 22C is based on a FSPDN. The processor die 2204 includes a first substrate 2212, a first interconnect structure 2244 and a second interconnect structure 2246. According to some embodiments, the first substrate 2212 includes a plurality of through vias 2222 traversing the first substrate 2212 and electrically connecting the first interconnect structure 2244 and the second interconnect structure 2246. According to some embodiments, the first substrate 2212 has a front side, which may include a front-end-of-line (FEOL) structure, facing the second interconnect structure 2246, and a backside facing the first interconnect structure 2244.

According to some embodiments, the first interconnect structure 2244 is disposed between the first substrate 2212 and the connectors 266 immediately adjacent to the first interconnect structure 2244, and electrically connects the first substrate 2212 to its closest heat spreader 910 through the first interconnect structure 2244. Similarly, the second interconnect structure 2246 is disposed between the first substrate 2212 and the connectors 264 immediately adjacent to the second interconnect structure 2246, and electrically connects the first substrate 2212 to the interposer 230 through the second interconnect structure 2246. According to some embodiments, power and ground are provided to the front side of the first substrate 2212 through the substrate 210, the interposer 230 and the second interconnect structure 2246. In contrast to the BSPDN adopted by the processor die 2202 shown in FIG. 22A or 22B, the processor die 2204 in FIG. 22C is based on a FSPDN. Such power/ground delivery arrangement provides an alternative to BSPDN when it comes to power delivery, signaling and heat dissipation.

FIG. 22D shows a cross-sectional view of a semiconductor package 2200D, in accordance with some embodiments of the present disclosure. The semiconductor package 2200D is similar to the semiconductor package 2200A or 2200C, and similar features are not repeated for brevity. The main difference between the semiconductor package 2200D and the semiconductor package 2200A or 2200C is that the semiconductor package 2200D further includes one or more interposers or spacers 2240 adjacent to the processor die 2202, the control die 254, and/or the memory dies 252. The interposers 2240 may be configured as spacers and arranged on the sides of the respective dies, 2202, 254 and/or 252. According to some embodiments, the interposers 2240 are made of a substrate, which is formed of diamond, silicon, boron nitride, aluminum nitride, silicon carbide, a combination thereof, or other suitable low-CTE and preferably high-TC materials; and one or more through vias 920 in the substrate which are formed of materials configured for electrical interconnection, optical interconnection or for heat dissipation, or which contain empty fluidic channels for liquid coolant to flow through to enhance heat dissipation. According to some embodiments, the interposers 2240 are bonded to their overlying and underlying features through connectors, e.g., connectors, 264, 266 and 268.

FIG. 22E shows a cross-sectional view of a semiconductor package 2200E, in accordance with some embodiments of the present disclosure. The semiconductor package 2200E which is based on a FSPDN is similar to the semiconductor package 2200C, and similar features are not repeated for brevity. The main difference between the semiconductor packages, 2200E and 2200C is that the processor die 2212 of the semiconductor package 2200C is replaced with a processor-HTC interposer combo 2206′ in the semiconductor package 2200E. The processor die 2206 is copper hybrid bonded to an HTC interposer 910′, such as a diamond interposer, to form a processor-HTC interposer combo 2206′. As depicted in FIG. 22E, the processor die 2206 and the HTC interposer 910′ have the same width, however, in other non-illustrated embodiments, the processor die 2206 and the HTC interposer 910′ can assume different widths, for example, the HTC interposer 910′ can be wider than the processor die 2206 and permit the heat spreader 280 to be disposed thereon to enhance heat dissipation. The processor-HTC interposer combo 2206′ as shown in FIG. 22E is flip chip bonded to the substrate 210 underneath it through the connectors 264 and electrically connected with an overlying heat spreader 910 through the connectors 266. According to some embodiments, the processor-HTC interposer combo can alternatively have the processor 2206 mounted underneath the HTC interposer 910′ and directly bonded to the underlying substrate in the semiconductor package 2200E.

FIG. 22F shows a cross-sectional view of the processor-HTC interposer combo 2206′ in the semiconductor package 2200E as shown in FIG. 22E, in accordance with some embodiments of the present disclosure. The processor die 2206 is similar to the processor die 2212 in FIG. 22C, and similar features are not repeated for brevity.

According to some embodiments, the processor-HTC interposer combo 2206′ further includes a first bonding structure 2254, a second bonding structure 2256, an HTC interposer 910′ and an interconnect structure 2258 on a side of the HTC interposer 910′ facing away from the processor die 2206. The first bonding structure 2254 and/or the second bonding structure 2256 may include one or more conductive wiring layers and conductive via layers to form one or more interconnection routes between the interconnect structure 2258 and the HTC interposer 910′. According to some embodiments, the first bonding structure 2254 and the second bonding structure 2256 have respective bonding layers bonded to each other. The first and second bonding structures, 2254 and 2256, may contain hybrid bonding layers comprising metallic bonding pads, 2274 and 2284, and dielectric bonding surfaces adjacent to the metallic bonding pads, 2274 and 2284, so as to form a metallic bonding interface and a dielectric bonding interface, respectively, between the bonding structures, 2254 and 2256.

According to some embodiments, the HTC interposer 910′ further includes through vias 2262 extending through the HTC interposer 910′. According to some embodiments, the through vias 2262 are configured as thermal vias for conducting heat, electrical vias or optical vias for connecting the second bonding structure 2256 and the interconnect structure 2258. According to some embodiments, the interconnect structure 2258 are configured to electrically connect the HTC interposer 910′ to the connectors 264. The material and configuration of the interconnect structure 2258 are similar to those of the interconnect structures, 2210, 2216, 2218, 2224 or 2254, or 2256, and details are not repeated for brevity.

Furthermore and referring to FIG. 22E, the semiconductor package 2200E may further include heat spreaders 2207 which may contain built-in vapor chambers on the sides of the memory dies 252 for enhanced heat dissipation performance through adjacent heat spreaders 910.

According to some embodiments, the exposed surfaces of the processor die 2206 are coated with the coating 610, as illustrated by an enlarged portion of the semiconductor package 2200E shown on the right side of FIG. 22E.

FIG. 22G shows a cross-sectional view of a semiconductor package 2200G, in accordance with some embodiments of the present disclosure. The semiconductor package 2200G is similar to the semiconductor package 2200D or 2200E, and similar features are not repeated for brevity. The main difference between the semiconductor package 2200G and the semiconductor package 2200D or 2200E is that the semiconductor package 2200G has a different arrangement of the interposers 2242 between the control die 254 and the processor die 2202. As shown in FIG. 22G, two interposers 2242 are arranged between the processor die 2202 and the control die 254, creating an air gap between the hot processor die 2202 and the control die 254 to block the heat flow from the processor die 2202 towards the control die 254 for air cooling or direct-to-chip liquid applications, or alternatively to allow the liquid coolant to flow through the gap and cool the hot processor die for liquid immersion cooling applications. The materials and configurations of the interposer 2242 are similar to those of the interposer 2240, and similar features are not repeated for brevity. According to some embodiments, the interposers 2242 are electrically connected to the processor die 2202 and the control die 254 through the connectors 264 and 266, respectively.

According to some embodiments, the semiconductor package 2200G further includes heat spreaders 292. The heat spreaders 292 may be made of a material similar to that used in forming the aforementioned heat spreaders, the CTE adjusters 1014 discussed with reference to FIGS. 10A to 10D, or alternatively, the material of the second substrate 2226 discussed with reference to FIG. 22B. According to some embodiments, the heat spreader 292 assumes a square shape, a column shape, a bar shape or a strip shape, and may be referred to as a heat dissipation bridge. The heat spreaders 292 may extend between the bottom portion of the heat spreader 280 and top portion of the interposer 230 as shown in FIG. 22G and it may contain empty spaces to allow liquid coolant to flow through According to some embodiments, the heat spreader 292 are thermally connected to the interposer 230 through a high-TC bonding or adhesive layer 284. Without the presence of the liquid coolant in a liquid immersion application, heat generated by the processor die 2202 is first transferred to the interposer 230 through the BSPDN of the processor die 2202 and the heat absorbed by the interposer 230 is then conducted to the heat spreader 280 through the heat spreaders 292, thereby improving heat dissipation efficiency. This can improve cooling efficiencies in liquid immersion cooling applications.

According to some embodiment, the coating 610 is coated directly on the exposed surfaces of the processor die 2202, the control die 254, the interposers 2242 and the connectors, 264 and 266, as illustrated by an enlarged portion of the semiconductor package 2200G on the right side of FIG. 22G.

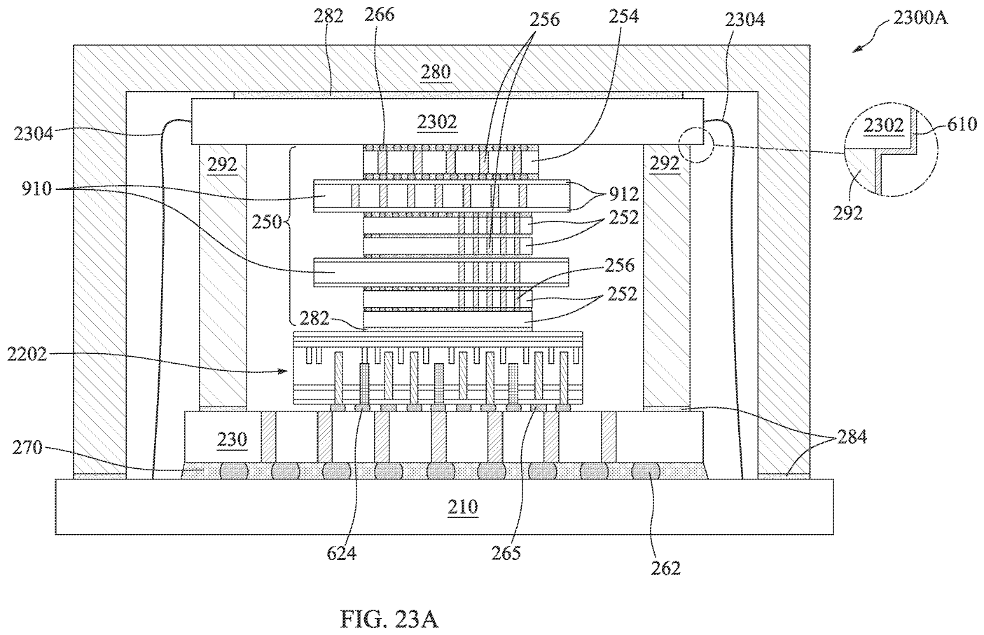

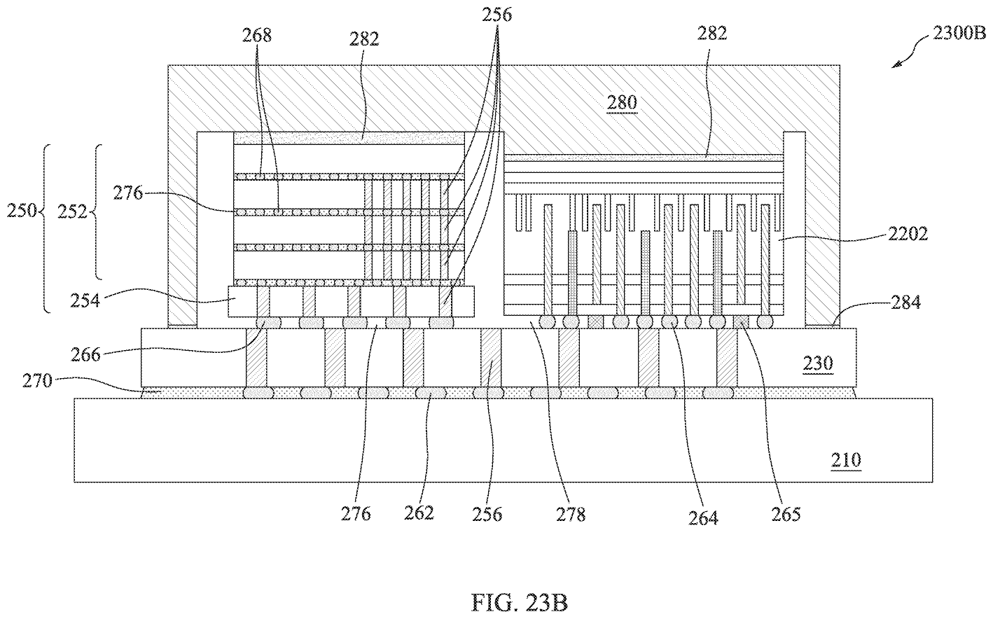

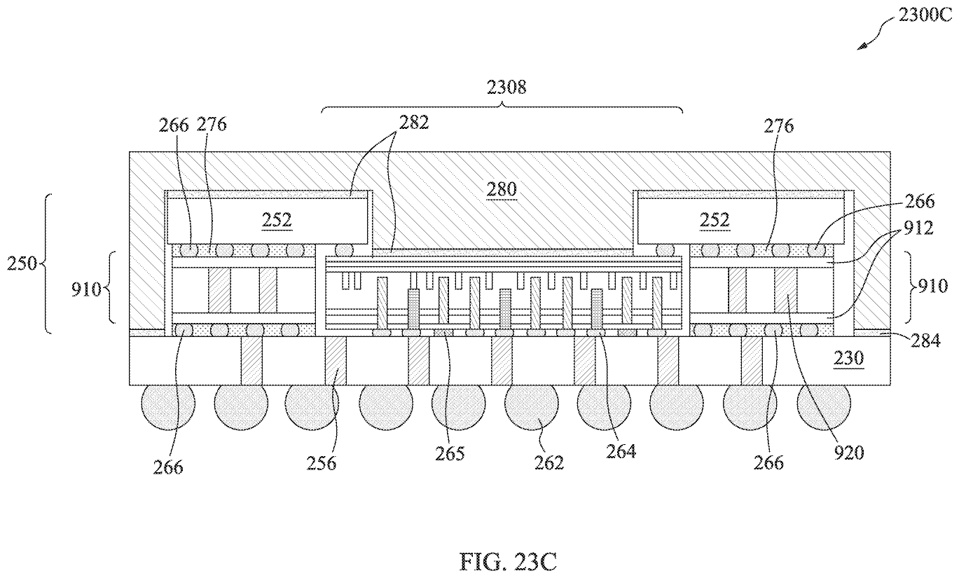

FIG. 23A shows a cross-sectional view of a semiconductor package 2300A, in accordance with some embodiments of the present disclosure. The semiconductor package 2300A is similar to the semiconductor package 2200A in FIG. 22A, and similar features are not repeated for brevity. The main difference between the semiconductor package 2300A and the semiconductor package 2200A has to do with semiconductor package 2300A adopting a reverse stacking of the HBM dies 252 on the processor die 2202 in comparison with the semiconductor package 2200A. As opposed to staking the control die 254 of the memory stack directly on the processor die 2202 as shown in FIG. 22A, the top DRAM die 252 (containing through vias; not shown) in the memory stack 250 is bonded directly on the processor die 2202 as shown in FIG. 23A, and the control die 254 appearing on top of the HBM stack 250 is interconnected to the first substrate 210 through a flexible connector 2304.

The semiconductor package 2300A may further include a circuit die 2302 or a HTC circuit layer arranged between a thermal interface material 282 and the control die 254 connecting the flexible connector 2304 to the control die 254 and to the first substrate 210. According to some embodiments, the flexible connectors 2304 are referred to as flexible circuit interconnects (flexes) 2304 which are used to electrically connect and power the dies in the HBM stack 250 through the first substrate 210. The flexible circuit interconnects 2304 may be used to transmit power or data/control signals between the first substrate 210 and the memory stack 250 through the circuit elements of 2302. According to some embodiments, the flexible circuit interconnects 2304 are formed of flexible printed circuits.

According to some embodiment, the coating 610 is coated directly on the exposed surfaces of the processor die 2202, the control die 254, the interposers 910, the connectors 264, the enhancing structure 265 and the circuit die 2302, as illustrated by an enlarged portion of the semiconductor package 2300A on the right side of FIG. 23A. Although not separately shown, the coating 610 is also coated on the exposed surfaces of the flexible circuit interconnects 2304.

FIG. 23B shows a cross-sectional view of a semiconductor package 2300B in 2.5D package configuration, in accordance with some embodiments of the present disclosure. The semiconductor package 2300B is similar to the semiconductor package 700B shown in FIG. 7B, and similar features are not repeated for brevity. The main difference between the semiconductor package 2300B and the semiconductor package 700B is that the processor die 242 of the semiconductor package 700B based on a FSPDN is replaced with the processor die 2202 based on a BSPDN in the semiconductor package 2300B. Although not separately shown, the processor die 2202 can be replaced with other processor dies described herein with suitable interconnect structures. As shown in FIG. 23B, the interposer 230 of the semiconductor package 2300B is directly bonded to the substrate 210 which is typically a laminate substrate that is bonded to a PCB (not shown). The heat spreader 280 of the semiconductor package 2300B is thermally coupled to the interposer 230.

Although not separately shown, the coating 610 is coated on the exposed surfaces of the components of the semiconductor package 2300B, e.g., the exposed surfaces of the connectors, 264 and 266, the processors die 2202 and the enhancing structure 265.

FIG. 23C shows a cross-sectional view of a semiconductor package 2300C, in accordance with some embodiments of the present disclosure. The semiconductor package 2300C can be seen as a variant of the semiconductor package 2300B, and therefore similar features are not repeated for brevity. The main difference between the semiconductor package 2300C and the semiconductor package 2300B is that the control die 254 (not shown in FIG. 23C) appearing on the bottom of the memory stack 252 in the semiconductor package 2300B is partly mounted on an interposer 910 in the semiconductor package 2300C and partly mounted on the processor die 2202. The memory dies 252 may be partially overlapped with the processor die 2308 from a top-view perspective, and the heat spreader 280 is arranged to be thermally coupled to the processor die 2308 and the memory dies 252 through die top surfaces to facilitate heat dissipation. According to some embodiments, one or more interposers, 910 which can be of the same or different construction, are arranged between the interposer 230 and the respective memory dies 252 to provide additional heat dissipation paths for the memory dies 252. Memory dies which are mounted on the periphery of the processor die prevent the bulk of the heat flow from the hot processor from reaching memory dies. Moreover, the semiconductor package 2300C may be considered as one type of a 2.5D IC in that the memory dies 252 can be electrically coupled to the processor die 2308 through the underlying interposers, 910 and 230.

Although not separately shown, the coating 610 is coated on the exposed surfaces of the components of the semiconductor package 2300C, e.g., the exposed surfaces of the connectors, 264 and 266, the interposers, 910, the enhancing structure 265 and the processors die 2308.

The foregoing outlines structure of several embodiments so that those skilled in the art may better understand the aspects of the present disclosure. Those skilled in the art should appreciate that they may readily use the present disclosure as a basis for designing or modifying other operations and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package, comprising:
a first semiconductor die disposed over a first substrate;
a plurality of second semiconductor dies disposed over the first semiconductor die or adjacent to the first semiconductor die;
a plurality of first connectors arranged between and electrically connecting the first semiconductor die and the first substrate;
a plurality of second connectors arranged between and electrically connecting two of the second semiconductor dies;
a first dielectric layer encapsulating the plurality of second connectors; and
a dielectric coating, different from the first dielectric layer, conformally formed on exposed surfaces of the plurality of first connectors and laterally surrounding the first dielectric layer,
wherein a plurality of air gaps are arranged between the plurality of first connectors.

2. The semiconductor package of claim 1, wherein the air gaps are configured to allow passage of liquid coolant under an immersion cooling operation.

3. The semiconductor package of claim 1, wherein the dielectric coating is further formed on an exposed lower surface of the first semiconductor die and an exposed upper surface of the first substrate to define the air gaps.

4. The semiconductor package of claim 1, wherein the dielectric coating comprises parylene.

5. The semiconductor package of claim 1, wherein the first dielectric layer fills spaces between two of the second semiconductor dies.

6. The semiconductor package of claim 1, wherein each of the first semiconductor die, the plurality of second semiconductor dies, and the first substrate comprises a plurality of first through vias.

7. The semiconductor package of claim 1, further comprising a first heat spreader arranged between the first semiconductor die and the plurality of second semiconductor dies.

8. The semiconductor package of claim 1, further comprising:
a second substrate disposed below the first substrate;
a plurality of third connectors arranged between and electrically connecting the first substrate and the second substrate; and
a second dielectric layer encapsulating the plurality of third connectors,
wherein the dielectric coating is further formed over exposed surfaces of the second substrate and the second dielectric layer.

9. The semiconductor package of claim 1, further comprising a second heat spreader coupled to the first substrate, wherein the second heat spreader comprises a through via extending through the second heat spreader.

10. The semiconductor package of claim 1, further comprising a third heat spreader disposed over the plurality of second semiconductor dies, and the first substrate wherein the dielectric coating is further formed on exposed surfaces of the third heat spreader and the first substrate.

11. A semiconductor package, comprising:
a first semiconductor die arranged over a substrate;
a plurality of second semiconductor dies over the first semiconductor die or adjacent to the first semiconductor die;
a plurality of first connectors arranged between and electrically connecting the first semiconductor die and the substrate;
a plurality of second connectors arranged between and electrically connecting two of the second semiconductor dies;
a first dielectric layer encapsulating the plurality of second connectors;
a plurality of enhancing structures adjacent to the first semiconductor die, wherein the plurality of enhancing structures are arranged proximal to the plurality of first connectors and the substrate, surrounding, or over the first semiconductor die; and
a dielectric coating, different from the first dielectric layer, conformally formed on exposed surfaces of the plurality of first connectors and the plurality of enhancing structures, and laterally surrounding the first dielectric layer.

12. The semiconductor package of claim 11, wherein the plurality of enhancing structures are arranged to cover corners of the first semiconductor die from a top-view perspective.

13. The semiconductor package of claim 11, wherein each of the plurality of enhancing structures comprises a first conductive plug, a second conductive plug over the first conductive plug, and a soft metal or solder material connecting the first conductive plug and the second conductive plug, wherein the first conductive plug and the second conductive plug have a first height greater than a second height of the soft metal or solder material.

14. The semiconductor package of claim 11, wherein the plurality of enhancing structures comprise a stress compensation layer laterally surrounding a bottom portion of each of the plurality of first connectors.

15. The semiconductor package of claim 11, wherein the plurality of enhancing structures comprise a CTE adjuster coupled to the substrate, wherein the CTE adjuster comprises a CTE lower than that of the substrate and a TC higher than that of the substrate.

16. The semiconductor package of claim 11, wherein the plurality of enhancing structures comprise a stress compensation layer laterally surrounding each of the first connectors.

17. The semiconductor package of claim 11, wherein each of the enhancing structures comprises a conductive pad and a plurality of conductive bumps connected to the conductive pad.

18. A method of forming a semiconductor package, comprising:
forming a plurality of first connectors over a first semiconductor die;
bonding the first semiconductor die to a substrate through the plurality of first connectors;
forming a die stack over the first semiconductor die or adjacent to the first semiconductor die, wherein the die stack comprises a plurality of second semiconductor dies, a plurality of second connectors between two of the second semiconductor dies, and a first dielectric layer encapsulating the plurality of second connectors; and
depositing a dielectric coating, different from the first dielectric layer, on exposed surfaces of the substrate, the plurality of first connectors, the first semiconductor die, the plurality of second semiconductor dies, and the first dielectric layer,
wherein the deposition of the dielectric coating leaves a plurality of air gaps between the plurality of first connectors.

19. The method of claim 18, further comprising forming a plurality of enhancing structures between the first semiconductor die and the substrate, wherein the plurality of enhancing structures are formed on a periphery of the first semiconductor die, and wherein the dielectric coating is further formed on exposed surfaces of the plurality of enhancing structures.

20. The method of claim 19, wherein the plurality of enhancing structures at least cover sidewalls of the first semiconductor die, or extend to a depth of the substrate.
